(19) United States
(12) Patent Application Publication
(10) Pub. No.: US 2026/0052884 A1
(43) Pub. Date: Feb. 19, 2026

(54) ELECTRONIC DEVICE AND MANUFACTURING METHOD OF THE SAME

(71) Applicant: Samsung Display Co., Ltd., Yongin-si (KR)

(72) Inventors: JAEHEUNG HA, Yongin-si (KR); JONGWOO KIM, Yongin-si (KR); HYUNSUP YOON, Yongin-si (KR)

(21) Appl. No.: 19/265,689

(22) Filed: Jul. 10, 2025

(30) Foreign Application Priority Data
Aug. 19, 2024 (KR) 10-2024-0110560

(51) Int. Cl. H10K 59/80; H10K 59/65; H10K 102/00

(52) U.S. Cl. CPC H10K 59/873; H10K 59/65; H10K 2102/351

(57) ABSTRACT

An electronic device and a method for manufacturing the electronic device are disclosed. The electronic device may include an electronic module and a display module including a hole region to overlap the electronic module, wherein the display module includes a base layer having a module hole that is defined therein and corresponds to the hole region, a circuit layer on the base layer, a display element layer provided on the circuit layer and including a light-emitting element, and an encapsulation layer partially provided on the display element layer and including at least a first inorganic layer, wherein the circuit layer includes a plurality of insulating layers provided on the base layer and including a first intermediate insulating layer, a first dam portion spaced from the first intermediate insulating layer, and a protrusion pattern provided on at least a portion of the first intermediate insulating layer and the first dam portion.

### CROSS-REFERENCE TO RELATED APPLICATION

The present application claims priority to and the benefit of Korean Patent Application No. 10-2024-0110560, filed on Aug. 19, 2024, in the Korean Intellectual Property Office, the entire disclosure of which is incorporated herein by reference.

### BACKGROUND

### 1. Field

One or more embodiments of the present disclosure relate to an electronic device and a method for manufacturing the electronic device, and, for example, to an electronic device having improved or enhanced reliability and a method for manufacturing the electronic device.

### 2. Description of the Related Art

Electronic devices to provide images to a user, such as a television, a mobile phone, a tablet, a computer, a navigation system, a game console, and/or the like, may include a display panel to generate and display images. The electronic device may be composed of one or more suitable electronic components, such as an input sensor to sense an external input, an electronic module, and/or the like, in addition to the display panel. The electronic module may include a camera, an infrared sensor, and/or a proximity sensor.

In order to provide a wider display region to a user, the electronic module of the electronic device may be disposed or provided below the display panel, and a hole may be provided in the display panel to expose the electronic module. Also, more advanced technology is desired or required to protect one or more layers of the display panel, which are exposed around the hole, to ensure the reliability of the electronic device.

### SUMMARY

One or more aspects of embodiments of the present disclosure are directed toward an electronic device having improved or enhanced reliability due to a low water vapor transmission rate.

One or more aspects of embodiments of the present disclosure are also directed toward a method for manufacturing an electronic device that may improve or enhance the reliability of the electronic device through a simplified process.

Additional aspects of embodiments will be set forth in part in the description which follows and, in part, will be apparent from the description or may be learned by practice of the presented embodiments of the disclosure.

One or more embodiments of the present disclosure provide an electronic device that includes an electronic module and a display module including a hole region defined to overlap the electronic module, wherein the display module includes a base layer having a module hole that is defined therein and corresponds to the hole region, a circuit layer disposed or provided on the base layer, a display element layer disposed or provided on the circuit layer and including a light-emitting element, and an encapsulation layer partially disposed or provided on the display element layer and including at least a first inorganic layer, wherein the circuit layer includes a plurality of insulating (e.g., electrically insulating) layers disposed or provided on the base layer and including a first intermediate insulating (e.g., electrically insulating) layer, a first dam portion that is spaced and/or apart (e.g., spaced apart or separated) from the first intermediate insulating layer and defines at least one groove therebetween, and a protrusion pattern disposed or provided on at least a portion of the first intermediate insulating layer and the first dam portion and including a tip portion that protrudes in an inward direction of the at least one groove, wherein the first dam portion includes a first inclined surface disposed or provided below the protrusion pattern, and the first inorganic layer includes a first portion disposed or provided on the upper surface of the tip portion, a second portion disposed or provided on the lower surface of the tip portion, and a third portion disposed or provided on the first inclined surface, wherein the thickness of the second portion is about 30% or more of the thickness of the first portion, and the thickness of the third portion is about 40% or more of the thickness of the first portion.

In one or more embodiments, the at least one groove may include a first groove defined by the first inclined surface, the encapsulation layer may further include a second inorganic layer, and at least a portion of the first inorganic layer and at least a portion of the second inorganic layer may be in contact with each other in a region that overlaps the first groove.

In one or more embodiments, the first inorganic layer may further include a first sub-layer disposed or provided adjacent to the tip portion, a second sub-layer disposed or provided on the first sub-layer, and a third sub-layer disposed or provided on the second sub-layer. The density of the second sub-layer may be lower than the density of each of the first sub-layer and the third sub-layer.

In one or more embodiments, the thickness of the first sub-layer may be about 0.1% to about 10% of the thickness of the first inorganic layer.

In one or more embodiments, the density difference between the first sub-layer and the second sub-layer may be about 0.1 g/cm³ or more.

In one or more embodiments, the encapsulation layer may further include a second inorganic layer disposed or provided on the first inorganic layer and an organic layer disposed or provided between the first inorganic layer and the second inorganic layer. The organic layer may non-overlap (or may not overlap) at least a portion of the protrusion pattern on a plane (e.g., in plan view).

In one or more embodiments, each of the first inorganic layer and the second inorganic layer may include silicon nitride.

In one or more embodiments, the first dam portion may include a first dam layer disposed or provided on substantially the same layer as the first intermediate insulating layer and configured or arranged to provide a base surface on which the protrusion pattern is disposed or provided and a second dam layer disposed or provided on the protrusion pattern. The first inclined surface may be provided to the first dam layer.

In one or more embodiments, the refractive index of the first inorganic layer may be about 1.7 to about 2.0 at a wavelength of about 550 nm.

In one or more embodiments, the thickness of the first inorganic layer may be about 1,000 Å to about 20,000 Å.

In one or more embodiments, the water vapor transmission rate of the first inorganic layer may be 1.0×10⁻⁴ g/(m²·day) or less.

In one or more embodiments, the first inorganic layer may entirely (e.g., substantially entirely) cover the upper surface of the tip portion, the lower surface of the tip portion, and the side surface that connects the upper surface and the lower surface to each other.

In one or more embodiments, the first inorganic layer may entirely (e.g., substantially entirely) cover the first inclined surface.

In one or more embodiments, the plurality of insulating layers may further include a first lower insulating (e.g., electrically insulating) layer disposed or provided below the first intermediate insulating layer. The upper surface of the first lower insulating layer may be exposed by the at least one groove, and the first inorganic layer may be in contact with the upper surface of the first lower insulating layer.

In one or more embodiments, the at least one groove may be around (e.g., surround) the module hole on a plane (e.g., in plan view).

In one or more embodiments of the present disclosure, an electronic device includes an electronic module and a display module including a hole region defined to overlap the electronic module. The display module includes a base layer having a module hole that is defined therein and corresponds to the hole region, a circuit layer disposed or provided on the base layer, a display element layer disposed or provided on the circuit layer and including a light-emitting element, and an encapsulation layer partially disposed or provided on the display element layer and including a first inorganic layer and a second inorganic layer. The circuit layer includes a dam pattern disposed or provided in the hole region and including a first dam portion and a second dam portion and a protrusion pattern disposed or provided on at least a portion of the dam pattern. A first groove is defined between the first dam portion and the second dam portion, the protrusion pattern includes a tip portion that protrudes in an inward direction of the first groove, and each of the first dam portion and the second dam portion includes a first inclined surface that is disposed or provided below the protrusion pattern and defines the first groove. The first inorganic layer includes a first portion disposed or provided on the upper surface of the tip portion, a second portion disposed or provided on the lower surface of the tip portion, and a third portion disposed or provided on the first inclined surface. The thickness of the second portion is about 30% or more of the thickness of the first portion, and the thickness of the third portion is about 40% or more of the thickness of the first portion.

In one or more embodiments of the present disclosure, a method for manufacturing an electronic device includes providing a base layer having a module hole defined therein, forming or providing a circuit layer including a plurality of insulating (e.g., electrically insulating) layers on the base layer, a dam pattern spaced and/or apart (e.g., spaced apart or separated) from the plurality of insulating layers, and a protrusion pattern, and forming or providing an encapsulation layer on the circuit layer. The dam pattern includes a first dam portion that is spaced and/or apart (e.g., spaced apart or separated) from the plurality of insulating layers and defines at least one groove therebetween. The protrusion pattern is disposed or provided on at least a portion of the first dam portion. The first dam portion includes a first inclined surface disposed or provided below the protrusion pattern, and the protrusion pattern includes a tip portion that protrudes from the first inclined surface. The forming or providing of the encapsulation layer includes forming or providing a first inorganic layer that covers the tip portion and the first inclined surface. The first inorganic layer includes a first portion disposed or provided on the upper surface of the tip portion, a second portion disposed or provided on the lower surface of the tip portion, and a third portion disposed or provided on the first inclined surface. The thickness of the second portion is about 30% or more of the thickness of the first portion, and the thickness of the third portion is about 40% or more of the thickness of the first portion.

In one or more embodiments, the forming or providing of the first inorganic layer may include applying a first deposition material by any one selected from among a plasma-enhanced atomic layer deposition (PEALD) method, a sputtering method, and an electron beam evaporator method to form or provide a preliminary first inorganic layer and applying a second deposition material on the preliminary first inorganic layer by a plasma-enhanced chemical vapor deposition (PECVD) method.

In one or more embodiments, the thickness of the preliminary first inorganic layer may be about 0.1% to about 10% of the total thickness of the first inorganic layer.

In one or more embodiments, the first inorganic layer may include a first sub-layer formed or provided to correspond to the preliminary first inorganic layer, a second sub-layer disposed or provided on the first sub-layer, and a third sub-layer disposed or provided on the second sub-layer. The density of the second sub-layer may be lower than the density of each of the first sub-layer and the third sub-layer.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a perspective view of an electronic device according to one or more embodiments of the present disclosure;

FIG. 2 is an exploded perspective view of the electronic device according to one or more embodiments of the present disclosure;

FIG. 3 is a cross-sectional view of a display module according to one or more embodiments of the present disclosure;

FIG. 4 is a plan view schematically illustrating a portion of the display module according to one or more embodiments of the present disclosure;

Each of FIGS. 5 and 6 is a cross-sectional view of a portion of the display module according to one or more embodiments of the present disclosure;

Each of FIGS. 7-9 is an enlarged cross-sectional view of a portion of the display module according to one or more embodiments of the present disclosure;

Each of FIGS. 10A-10C schematically illustrates one step of a method for manufacturing an electronic device according to one or more embodiments of the present disclosure;

Each of FIGS. 11A and 11B is an enlarged cross-sectional view of a portion of a display module in one step of the method for manufacturing the electronic device according to one or more embodiments of the present disclosure; and

FIG. 12 is an enlarged cross-sectional view of a portion of the display module in one step of the method for manufacturing the electronic device according to one or more embodiments of the present disclosure.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the accompanying drawings and the written description, and duplicative descriptions thereof may not be provided in the specification.

In the present disclosure, it will be understood that if (e.g., when) an element (or a region, a layer, a portion, and/or the like) is referred to as being “on”, “connected to”, or “coupled to” another element, it may be directly on, directly connected, or directly coupled to the other element, or intervening elements may be present therebetween. In contrast, if (e.g., when) an element is referred to as being “directly on”, “directly connected to”, or “directly coupled to” another element, there may be no intervening elements present therebetween.

In the present disclosure, the expression “being directly disposed” or “being directly provided” may refer to that there is no layer, film, region, plate, and/or the like which is added between a part of a layer, a film, a region, a plate, and/or the like and another part. For example, the expression “being directly disposed” may refer to being disposed or provided between two layers or two members without an additional member, such as an adhesive member therebetween.

In one or more embodiments, in the drawings, the thicknesses, ratios, and dimensions of components may be exaggerated for effective description of the technical features or contents.

As used herein, the term “and/or” includes any and all combinations that the associated components may define.

It will be understood that, although the terms first, second, and/or the like may be used herein to describe one or more suitable elements, these elements should not be limited by these terms. These terms are only used to distinguish one element from another element. For example, a first element may be termed a second element without departing from the scope of the present disclosure. Similarly, the second element may also be referred to as the first element. The terms of a singular form include plural forms unless otherwise specified.

In one or more embodiments, terms, such as “below”, “lower”, “above”, “upper” and/or the like, are used herein for ease of description to describe one element's relation to another element(s) as illustrated in the drawings. The above terms are relative concepts and are described based on the directions indicated in the drawings.

It will be understood that the terms “include”, “including”, “have”, and/or “having” if (e.g., when) used in the present disclosure specify the presence of stated features, integers, steps, operations, elements, components and/or combinations thereof, but do not preclude the presence or addition of one or more other features, integers, steps, operations, elements, components, and/or combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

In the context of the present application and unless otherwise defined, the terms “use,” “using,” and “used” may be considered synonymous with the terms “utilize,”“utilizing,”and “utilized,”respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical and scientific terms) used in the present disclosure have substantially the same meaning as generally understood by one of ordinary skill in the art to which the present disclosure belongs. In one or more embodiments, it will be further understood that terms, such as those defined in generally used dictionaries, should be interpreted as having a meaning that is consistent with their meaning in the context of the related technology and should not be interpreted in an idealized or overly formal sense unless expressly so defined herein.

Hereinafter, one or more embodiments of the present disclosure will be described in more detail with reference to the accompanying drawings.

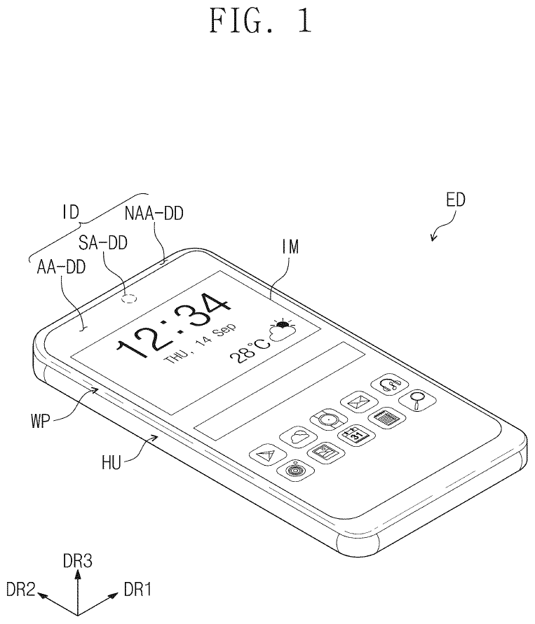

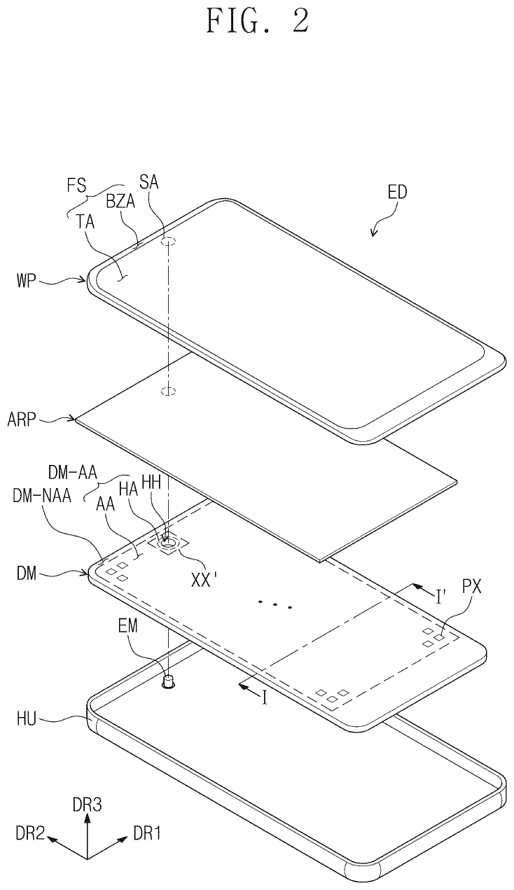

FIG. 1 is a perspective view of an electronic device according to one or more embodiments of the present disclosure. FIG. 2 is an exploded perspective view of the electronic device according to one or more embodiments of the present disclosure.

The electronic device ED may be activated according to an electrical signal and display an image. The electronic device ED may include one or more suitable embodiments that provide an image to a user, and, for example, the electronic device ED may be a large-sized device, such as a television, an outdoor billboard, and/or the like, as well as a small and medium-sized device, such as a monitor, a mobile phone, a computer, a tablet, a navigation system, a game console, and/or the like. One or more embodiments of the electronic device ED are exemplary and are not limited to any one embodiment as long as they do not depart from the concept or scope of the present disclosure. In FIG. 1 and/or the like of the present disclosure, a mobile phone is illustrated as an example of the electronic device ED.

Referring to FIG. 1, the electronic device ED may have a rectangular shape (e.g., a substantially rectangular shape) having short sides that extend in a first direction DR1 and long sides that extend in a second direction DR2 on a plane (e.g., in plan view). Without being limited thereto, however, the electronic device ED may have one or more suitable shapes, such as a circle (e.g., a substantially circle) or a polygon (e.g., a substantially polygon).

The electronic device ED may display an image IM in a third direction DR3 through a display surface IS parallel (e.g., substantially parallel) to a plane defined by the first direction DR1 and the second direction DR2. The third direction DR3 may be substantially parallel to the normal direction of the display surface IS. The display surface IS of the electronic device ED may correspond to the front surface of the electronic device ED.

The image IM displayed on the electronic device ED may include a moving image as well as a still image. FIG. 1 illustrates a clock window and a plurality of icons as examples of the image IM.

In one or more embodiments of the present disclosure, the front surface (or upper surface) and the rear surface (or lower surface) of each member or unit may be defined based on a direction in which the image IM is displayed. The front surface and the rear surface may be opposed to each other in the third direction DR3, and the normal direction of each of the front surface and the rear surface may be substantially parallel to the third direction DR3. The separation distance between the front surface and the rear surface defined along the third direction DR3 may correspond to the thickness of a member (or unit).

In the present disclosure, the expression “on a plane” or “in plan view” may be defined as a state viewed from the third direction DR3. In the present disclosure, the expression “on a cross section” may be defined as a state viewed from the first direction DR1 or the second direction DR2. In one or more embodiments, the directions indicated by the first direction DR1, the second direction DR2, and the third direction DR3 are relative concepts and may be converted into other directions.

The electronic device ED may be a flexible device. The expression “being flexible” refers to a property of being bendable, and a flexible structure may include everything from a completely foldable structure to a structure that can be bent to the level of several nanometers. For example, a flexible electronic device DD may include a curved device or a foldable device. Without being limited thereto, the electronic device ED may be a rigid one.

FIG. 1 illustrates an example of the electronic device ED having a flat display surface IS. However, the shape of the display surface IS of the electronic device ED is not limited thereto and may be curved or three-dimensional.

The display surface IS of the electronic device ED may include a display portion AA-DD and a non-display portion NAA-DD. The display portion AA-DD may be a portion, on which an image IM is displayed, within the front surface of the electronic device ED, and a user may view the image IM through the display portion AA-DD. This embodiment illustrates an example of the display portion AA-DD having a tetragonal shape (e.g., a substantially tetragonal shape) on a plane (e.g., in plan view), but the display portion AA-DD may have one or more suitable shapes depending on the design of the electronic device ED.

The non-display portion NAA-DD may be a portion, on which an image IM is not displayed, within the front surface of the electronic device ED. The non-display portion NAA-DD may have a set or predetermined color and be a portion that blocks light (or reduces a degree or occurrence of light). The non-display portion NAA-DD may be adjacent to the display portion AA-DD. For example, the non-display portion NAA-DD may be disposed or provided outside and be around (e.g., surround) the display portion AA-DD. However, this is illustrated as an example, and the non-display portion NAA-DD may be adjacent to only one side of the display portion AA-DD or may be disposed or provided on a side surface other than the front surface of the electronic device ED. In one or more embodiments, without being limited thereto, the non-display portion NAA-DD may not be provided.

The display portion AA-DD of the electronic device ED according to one or more embodiments of the present disclosure may include a sensing region SA-DD. The sensing region SA-DD may correspond to a region that an electronic module EM of FIG. 2 overlaps. The electronic module EM (see FIG. 2) may receive an external input transmitted through the sensing region SA-DD or output a signal through the sensing region SA-DD. FIG. 1 exemplarily illustrates one sensing region SA-DD disposed or provided within the display portion AA-DD, but embodiments of the present disclosure are not limited thereto, and the sensing region SA-DD may be provided in plurality within the display portion AA-DD.

The electronic device ED according to one or more embodiments of the present disclosure may sense an external input applied from the outside. The external input may have one or more suitable forms, such as pressure, temperature, and/or light, which are provided from the outside. The external input may include not only an input in contact with the electronic device ED (for example, a touch by a user's hand and/or a pen), but also an input applied in close proximity to the electronic device ED (for example, hovering).

Referring to FIGS. 1 and 2, the electronic device ED may include a window WP and a housing HU. The window WP and the housing HU may be coupled to each other to form or provide the exterior of the electronic device ED, providing an internal space capable of accommodating the components of the electronic device ED. The electronic device ED may include a display module DM, a light control member ARP, and an electronic module EM that are disposed or provided between the window WP and the housing HU.

The electronic module EM may be disposed or provided below the display module DM. The electronic module EM may be disposed or provided to overlap the display module DM. The electronic module EM may be an electronic component configured or provided to output or receive an optical signal. For example, the electronic module EM may be a camera module to capture an external image. Without being limited thereto, the electronic module EM may be a sensor module, such as a proximity sensor and/or an infrared light-emitting sensor.

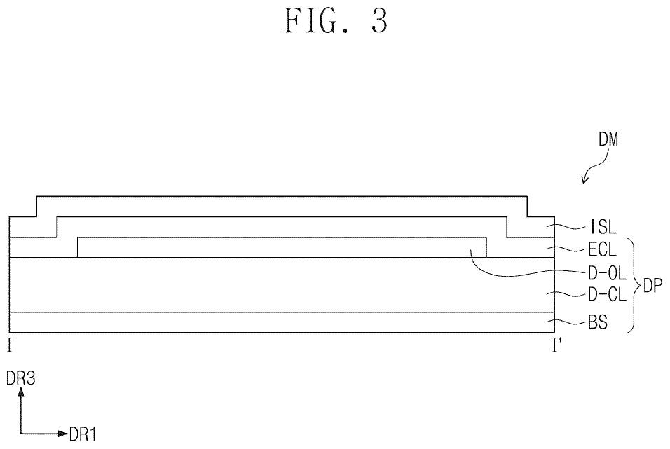

The display module DM may be disposed or provided on the electronic module EM. The display module DM may include a display panel DP (see FIG. 3) to be described herein. The display panel DP (see FIG. 3) may generate an image according to an electrical signal. The display panel DP (see FIG. 3) may be a light-emitting display panel, but embodiments of the present disclosure are not limited thereto.

The display module DM may include an active region DM-AA and a peripheral region DM-NAA adjacent to the active region DM-AA. The active region DM-AA may be activated according to an electrical signal. A plurality of pixels PX may be disposed or provided in the active region DM-AA.

The peripheral region DM-NAA may be around (e.g., surround) the active region DM-AA. A driving circuit or a driving line to drive the pixels PX disposed or provided in the active region DM-AA, one or more suitable signal lines or pads to provide electrical signals to an element, and/or the like may be disposed or provided in the peripheral region DM-NAA.

The display module DM may include a hole region HA located or provided within the active region DM-AA. The hole region HA may correspond to the sensing region SA-DD as described in one or more embodiments. In one or more embodiments, the expression “a region/portion corresponds to another region/portion” refers to that “the regions/portions overlap each other” and the expression is not limited to having substantially the same area and/or substantially the same shape. The hole region HA may also be referred to as a first region HA.

The hole region HA may overlap the electronic module EM. A module hole HH that passes through the display module DM may be defined in the hole region HA. The module hole HH may overlap the electronic module EM. In one or more embodiments of the present disclosure, a portion of the electronic module EM may be inserted into the module hole HH.

In FIG. 2, one module hole HH having a circular shape (e.g., a substantially circular shape) is illustrated as an example, but embodiments of the present disclosure are not limited thereto. The module hole HH may be defined in plurality so that the number of the module holes HH may correspond to the number of the electronic modules EM disposed or provided below the display module DM. In one or more embodiments, the shape of the module hole HH on a plane (e.g., in plan view) may be a polygon (e.g., a substantially polygon), an oval (e.g., a substantially oval), and/or the like, and the shape of the module hole HH on a plane (e.g., in plan view) may be provided in one or more suitable forms according to the shape or arrangement of the electronic module EM.

The electronic device ED may receive an external signal desired or required for the electronic module EM through the hole region HA or provide a signal output from the electronic module EM to the outside. According to the present disclosure, because the hole region HA is provided within the active region DM-AA, the area of the non-display portion NAA-DD to dispose or provide the electronic module EM may be reduced.

At least a portion of the hole region HA may be surrounded by the display region AA. The display region AA may be referred to as a second region. The active region DM-AA of the display module DM according to one or more embodiments of the present disclosure may include a hole region HA and a display region AA. In one or more embodiments of the present disclosure, the hole region HA may be completely (e.g., substantially completely) surrounded by the display region AA, but embodiments of the present disclosure are not limited thereto, and a portion of the hole region HA may be surrounded by the display region AA, and the remaining portion thereof may be in contact with the peripheral region DM-NAA.

The electronic device ED may include a light control member ARP disposed or provided between the display module DM and the window WP. The light control member ARP may be a reflection reduction layer that reduces the reflectance (or a degree or occurrence of the reflectance) of external light incident from outside the electronic device ED. However, embodiments of the present disclosure are not limited thereto, and the light control member ARP may include one or more suitable types or kinds of light control layers to improve or enhance the display quality of the electronic device ED. For example, the light control member ARP according to one or more embodiments of the present disclosure may include a polarizing layer, a phase retarder, a destructive interference structure, or a plurality of color filters. In one or more embodiments, in the electronic device ED according to one or more embodiments of the present disclosure, the light control member ARP may not be provided.

A portion of the light control member ARP that overlaps the hole region HA may have a relatively high light transmittance. For example, the light control member ARP may include a transmissive portion that overlaps the hole region HA, or without being limited thereto, the light control member ARP may also include a hole defined to overlap the hole region HA and pass through the light control member ARP.

The window WP may be disposed or provided on the light control member ARP. The window WP may protect the display module DM and the light control member ARP disposed or provided below the window WP.

The window WP may include an optically transparent (e.g., substantially transparent) insulating (e.g., electrically insulating) material. For example, the window WP may include glass, sapphire, plastic, and/or the like. The window WP may have a single-layer or a multi-layer structure. The window WP may further include functional layers, such as an anti-fingerprint layer, a phase control layer, and a hard coating layer, which are disposed or provided on an optically transparent (e.g., substantially transparent) substrate.

The front surface FS of the window WP may correspond to the display surface IS of the electronic device ED as described in one or more embodiments. The front surface FS of the window WP may include a transmissive region TA and a bezel region BZA.

The transmissive region TA of the window WP may be an optically transparent (e.g., substantially transparent) region. The transmissive region TA may correspond to the display portion AA-DD of the electronic device ED. The transmissive region TA may overlap at least a portion of the active region DM-AA of the display module DM. The window WP may transmit an image provided by the display module DM through the transmissive region TA, and a user may view the image.

The transmissive region TA of the window WP may include a sensing region SA. The sensing region SA of the window WP may correspond to the sensing region SA-DD of the electronic device ED. The sensing region SA of the window WP may overlap the hole region HA and the electronic module EM. The sensing region SA of the window WP may have a relatively high light transmittance. Accordingly, the electronic module EM may effectively or suitably receive an external input or output a signal through the sensing region SA.

The bezel region BZA of the window WP may be provided by depositing, coating, and/or printing a material having a set or predetermined color on a transparent (e.g., substantially transparent) substrate. The bezel region BZA may correspond to the non-display region NAA-DD of the electronic device ED. The bezel region BZA may overlap at least a portion of the peripheral region DM-NAA of the display module DM. Because the bezel region BZA of the window WP covers the peripheral region DM-NAA of the display module DM, it may be feasible to prevent the configuration or arrangement of the display module DM disposed or provided in the peripheral region DM-NAA from being viewed from the outside.

The housing HU may be disposed or provided below the display module DM. The housing HU may protect the components accommodated in the housing HU. The housing HU may prevent foreign substances, moisture, and/or the like from entering the display module DM (or reduce a degree to or occurrence of which foreign substances, moisture, and/or the like enter the display module DM) and the light control member ARP from the outside. The housing HU may include a material having relatively high rigidity, and the housing HU may absorb an impact applied from the outside. The housing HU may be provided in a form in which a plurality of storage members are coupled to each other.

FIG. 3 is a cross-sectional view of a display module according to one or more embodiments of the present disclosure. FIG. 3 schematically illustrates a cross section that corresponds to the line I-I′ of FIG. 2.

Referring to FIG. 3, the display module DM according to one or more embodiments may include a display panel DP and an input sensor ISL. The display panel DP may include a base layer BS, a circuit layer D-CL, a display element layer D-OL, and an encapsulation layer ECL.

The base layer BS may be a member that provides a base surface on which the circuit layer D-CL is disposed or provided. The base layer BS may be a rigid substrate or a flexible substrate capable of being bent, folded, or rolled. The base layer BS may be a glass substrate, a metal substrate, a silicon substrate, and/or a polymer substrate. However, embodiments of the present disclosure are not limited thereto, and the base layer BS may be an inorganic layer, an organic layer, or a composite material layer.

The circuit layer D-CL may be disposed or provided on the base layer BS. The circuit layer D-CL may include an insulating (e.g., electrically insulating) layer, a semiconductor pattern, a conductive (e.g., electrically conductive) pattern, and a signal transmission region. An insulating (e.g., electrically insulating) layer, a semiconductor layer, and a conductive (e.g., electrically conductive) layer may be formed or provided on the base layer BS by coating, deposition, and/or the like, and then the insulating (e.g., electrically insulating) layer, the semiconductor layer, and the conductive (e.g., electrically conductive) layer may be selectively patterned through a plurality of photolithography processes. Hereafter, a semiconductor pattern, a conductive (e.g., electrically conductive) pattern, and a signal line included in the circuit layer D-CL may be formed or provided.

The display element layer D-OL may be disposed or provided on the circuit layer D-CL. The display element layer D-OL may include a light-emitting element. For example, the display element layer D-OL may include an organic light-emitting material, an inorganic light-emitting material, an organic-inorganic light-emitting material, a quantum dot, a quantum rod, a micro LED, and/or a nano LED.

The encapsulation layer ECL may be disposed or provided on the display element layer D-OL. The encapsulation layer ECL may protect the display element layer D-OL from moisture, oxygen, and/or foreign substances, such as dust particles. The encapsulation layer ECL may be disposed or provided directly on the display element layer D-OL or coupled to the display element layer D-OL through a separate member.

In one or more embodiments of the present disclosure, the encapsulation layer ECL may include a plurality of layers, and at least one selected from among the plurality of layers may include an inorganic layer. For example, the encapsulation layer ECL may include a first inorganic layer IOL1 (see FIG. 5), an organic layer OL (see FIG. 5), and a second inorganic layer IOL2 (see FIG. 5). The encapsulation layer ECL will be described in more detail in the descriptions of FIG. 5.

In the display module DM according to one or more embodiments of the present disclosure, the input sensor ISL may be disposed or provided on the encapsulation layer ECL. The input sensor ISL may be formed or provided on the encapsulation layer ECL through a continuous (e.g., substantially continuous) process. In one or more embodiments, the input sensor ISL may be expressed as being disposed directly on the encapsulation layer ECL. Being directly disposed may refer to that no third component is disposed or provided between the input sensor ISL and the encapsulation layer ECL. For example, a separate adhesive material may not be disposed or provided between the input sensor ISL and the encapsulation layer ECL. In one or more embodiments, the input sensor ISL may be bonded to the encapsulation layer ECL by an adhesive member. The adhesive member may include an adhesive and/or a glue agent that are generally available or generally known.

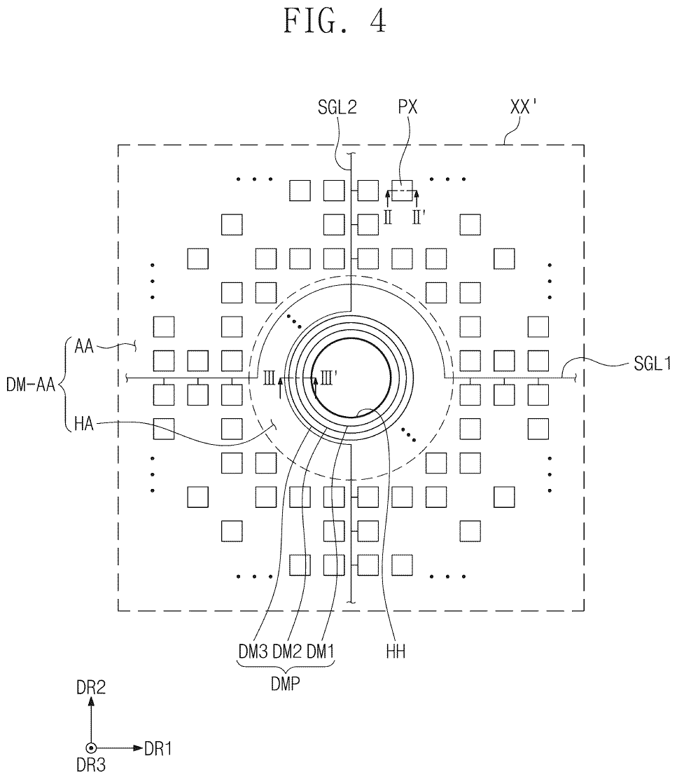

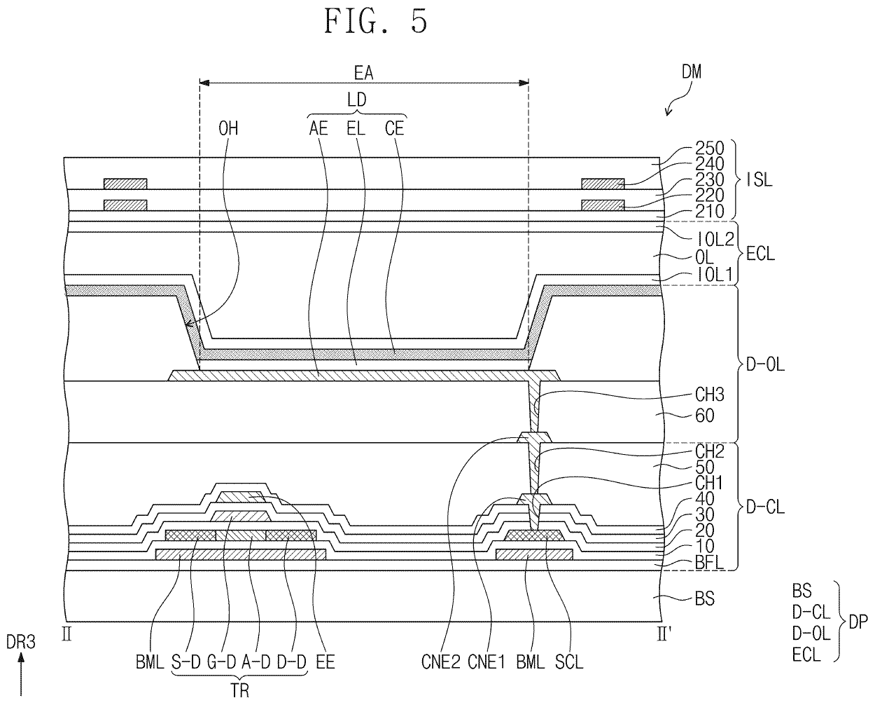

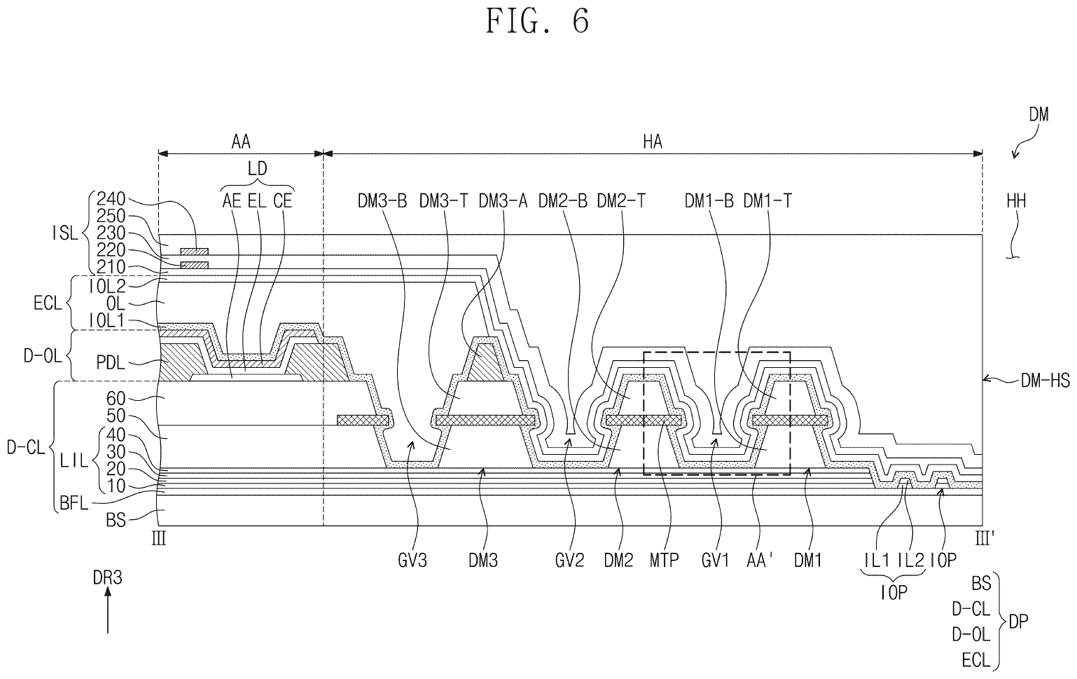

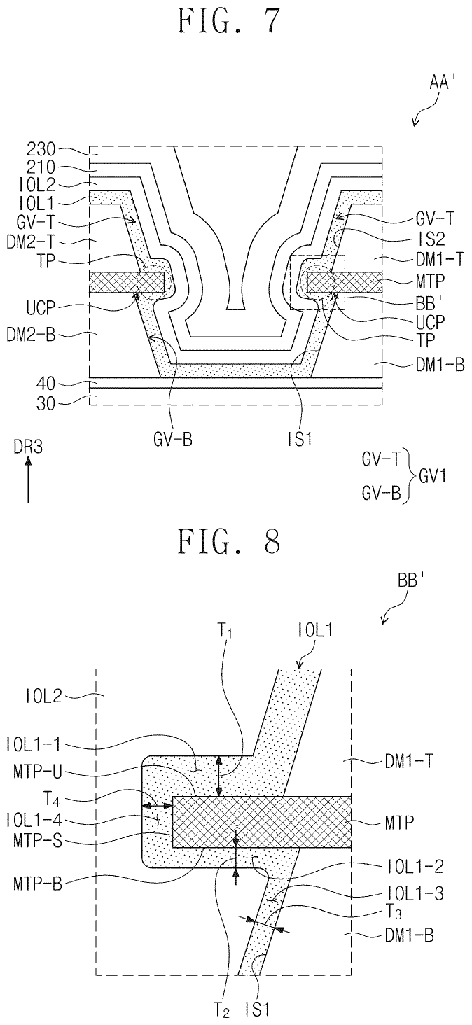

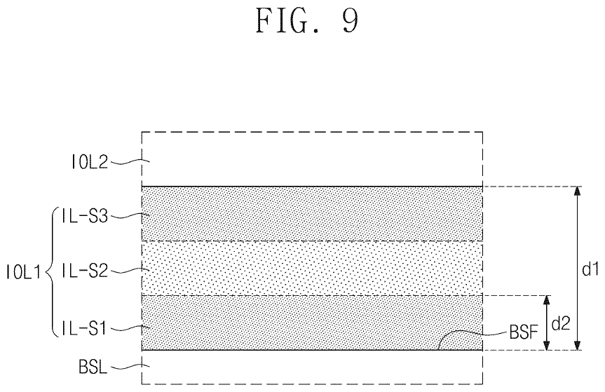

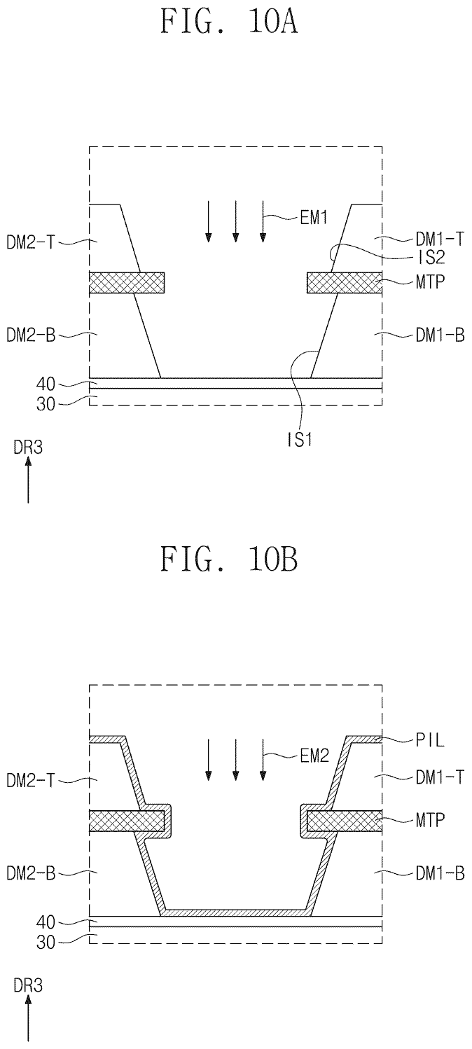

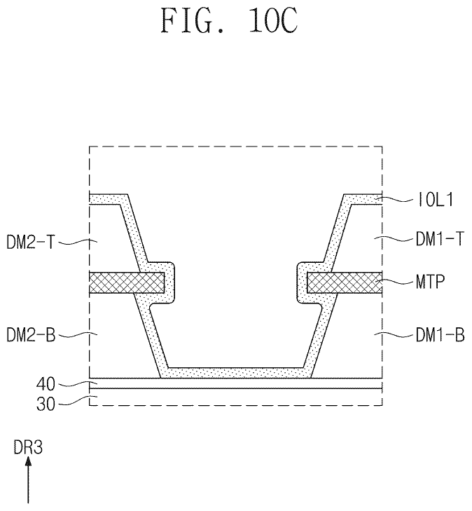

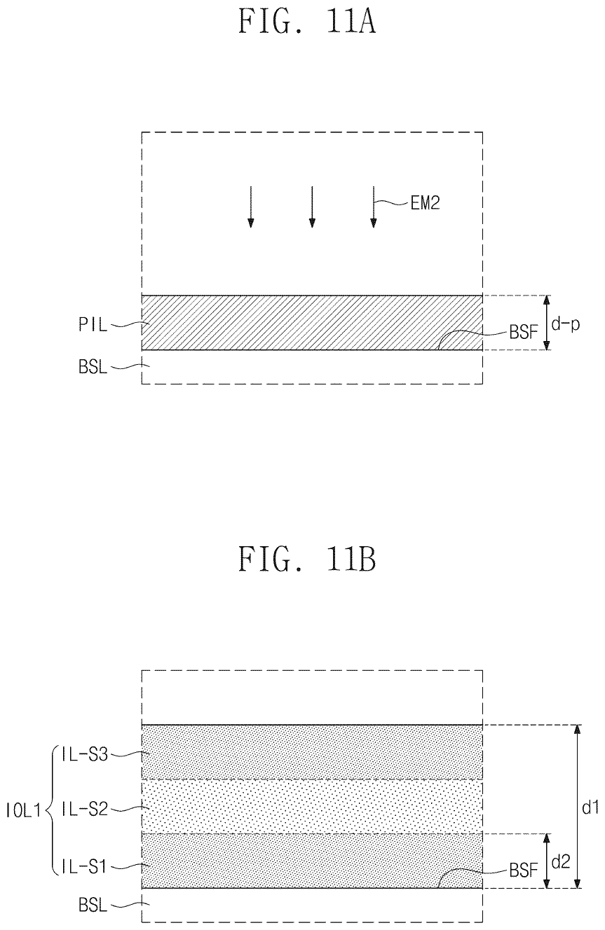

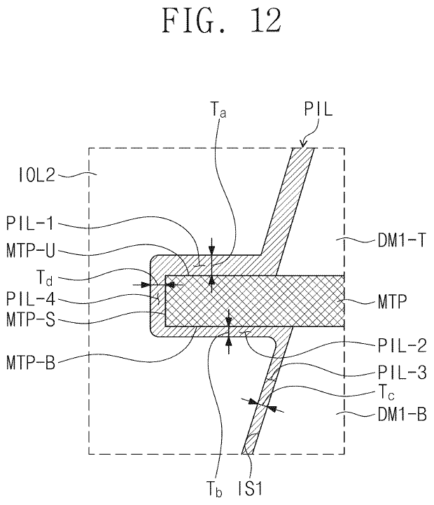

FIG. 4 is a plan view schematically illustrating a portion of the display module according to one or more embodiments of the present disclosure. FIG. 4 illustrates region XX′ of FIG. 2, and the region XX′ may correspond to a portion of the active region DM-AA including a module hole HH.

Referring to FIG. 4, a plurality of pixels PX may be disposed or provided in the active region DM-AA of the display module DM. In one or more embodiments of the present disclosure, most of the plurality of pixels PX may be disposed or provided in the display region AA (or second region) spaced and/or apart (e.g., spaced apart or separated) from the hole region HA, and one or more of the pixels PX may be disposed or provided in the display region AA along the boundary between the hole region HA (or first region) and the display region AA. The pixels PX adjacent to the boundary of the hole region HA may be disposed or provided to be spaced and/or apart (e.g., spaced apart or separated) from the module hole HH.

The module hole HH may be defined in the hole region HA. The module hole HH may be defined within the active region DM-AA. Accordingly, at least one or more of the pixels PX may be disposed or provided adjacent to the module hole HH, and, in one or more embodiments, the pixels PX may be disposed or provided to be spaced and/or apart (e.g., spaced apart or separated) from each other with the module hole HH therebetween. The electronic module EM may overlap the module hole HH.

A dam pattern DMP may be disposed or provided in the hole region HA. In the electronic device ED (see FIG. 2) according to one or more embodiments of the present disclosure, the dam pattern DMP may block a path through which moisture and/or oxygen flow from the module hole HH to the pixels PX. The dam pattern DMP may be disposed or provided in the hole region HA and include at least one selected from among dam portions DM1, DM2, and DM3. Each of the dam portions DM1, DM2, and DM3 may be around (e.g., surround) at least a portion of the module hole HH. According to one or more embodiments of the present disclosure, each of the dam portions DM1, DM2, and DM3 on a plane (e.g., in plan view) may have a closed-line shape around (e.g., surrounding) the module hole HH. Each of the dam portions DM1, DM2, and DM3 may be disposed or provided on substantially the same layer and formed or provided in substantially the same process as at least one or more of the insulating layers 10, 20, 30, 40, 50, and 60 (see FIG. 6) to be described herein in more detail.

At least one selected from among grooves GV1, GV2, and GV3 may be defined in the hole region HA. The grooves GV1, GV2, and GV3 may be defined to be around (e.g., surround) the module hole HH. The grooves GV1, GV2, and GV3 may be defined between the dam portions DM1, DM2, and DM3 or between at least one selected from among the dam portions and the display region AA. In one or more embodiments of the present disclosure, the grooves GV1, GV2, and GV3 may be defined by the dam portions DM1, DM2, and DM3 or the protrusion pattern MTP (see FIG. 6).

In one or more embodiments of the present disclosure, a filling material may be further disposed or provided inside the module hole HH. The filling material may include a polymer resin. As the filling material is disposed or provided inside the module hole HH, it may provide a flat surface (e.g., a substantially flat surface) to the components disposed or provided on the module hole HH. In one or more embodiments, a transparent (e.g., substantially transparent) material that does not have optical anisotropy may be used as the filling material. Any suitable material may be used as a filling material without limitation as long as it does not degrade the sensing capability of the electronic module EM (see FIG. 2). In one or more embodiments, the filling material may not be provided.

A portion of each of a plurality of signal lines SGL1 and SGL2 connected to the pixels PX may be disposed or provided in the hole region HA. The signal lines SGL1 and SGL2 are connected to the pixels PX spaced and/or apart (e.g., spaced apart or separated) from each other with the module hole HH therebetween via the hole region HA. For easy explanation, two signal lines SGL1 and SGL2 among the plurality of signal lines connected to the pixels PX are illustrated in FIG. 4 as an example.

A first signal line SGL1 extends along the first direction DR1. The first signal line SGL1 is connected to pixels in substantially the same row, which are arranged or provided along the first direction DR1 among the pixels PX. The first signal line SGL1 is exemplarily described as corresponding to any one selected from among scan lines connected to the pixels PX.

One or more of the pixels PX connected to the first signal line SGL1 are disposed or provided on the left side with the module hole HH as the center, while others are disposed or provided on the right side with the module hole HH as the center. Accordingly, the pixels PX in substantially the same row, which are connected to the first signal line SGL1, may be turned on/off by substantially the same scan signal even though one or more pixels are not provided around the module hole HH.

A second signal line SGL2 extends along the second direction DR2. The second signal line SGL2 is connected to pixels in substantially the same column, which are arranged or provided along the second direction DR2 among the pixels PX. The second signal line SGL2 is exemplarily described as corresponding to any one selected from among data lines connected to the pixels PX.

One or more of the pixels connected to the second signal line SGL2 are disposed or provided on the upper side with the module hole HH as the center, and others are disposed or provided on the lower side with the module hole HH as the center. Accordingly, the pixels in substantially the same column, which are connected to the second signal line SGL2, may receive a data signal through substantially the same line even though one or more pixels are not provided around the module hole HH.

At a point at which the first signal line SGL1 and the second signal line SGL2 cross each other, at least any one selected from the first signal line SGL1 and the second signal line SGL2 may be disconnected within the hole region HA, and a connection pattern that is disposed or provided on a layer different from that of the disconnected signal line and that connects the disconnected portion may be further included. However, the connection relationship of the pixels PX spaced and/or apart (e.g., spaced apart or separated) from each other with the module hole HH therebetween is not limited thereto.

Each of FIG. 5 and FIG. 6 is a cross-sectional view of a portion of the display module according to one or more embodiments of the present disclosure. FIG. 5 may illustrate a portion that corresponds to the line II-II′ of FIG. 4, and FIG. 6 may illustrate a portion that corresponds to the line III-III′ of FIG. 4. FIG. 5 illustrates a portion of the display region AA (see FIG. 4), and FIG. 6 illustrates a portion of the hole region HA (see FIG. 4).

Referring to FIG. 5 and FIG. 6, the display module DM may include a display panel DP and an input sensor ISP, and the display panel DP may include a base layer BS, a circuit layer D-CL, a display element layer D-OL, and an encapsulation layer ECL that are sequentially stacked.

FIG. 5 exemplarily illustrates a portion that corresponds to the pixel PX (see FIG. 4) as described in FIG. 4. FIG. 5 exemplarily illustrates one transistor TR and a light-emitting element LD included in the pixel PX (see FIG. 4).

The circuit layer D-CL may include a buffer layer BFL, a shielding electrode BML, a transistor TR, a signal transmission region SCL, a plurality of insulating layers 10, 20, 30, 40, 50, and 60, an upper electrode pattern EE, and a plurality of connection electrodes CNE1 and CNE2. In one or more embodiments, the circuit layer D-CL may further include a plurality of conductive (e.g., electrically conductive) patterns. For example, the circuit layer D-CL may further include additional conductive (e.g., electrically conductive) patterns that constitute a plurality of transistors, a capacitor, or a connection electrode in addition to the illustrated transistor TR. In one or more embodiments, the configuration or arrangement of the circuit layer D-CL as illustrated in FIG. 5 and/or the like is exemplary, and the type or kind, number, and arrangement location of the conductive (e.g., electrically conductive) patterns and the number of insulating (e.g., electrically insulating) layers may be changed.

The buffer layer BFL may be disposed or provided on the base layer BS. The buffer layer BFL may improve or enhance the bonding strength between the base layer BS and the semiconductor pattern or the conductive (e.g., electrically conductive) pattern disposed or provided on the buffer layer BFL. In one or more embodiments, the buffer layer BFL may prevent metal atoms and/or impurities from diffusing (or reduce a degree to or occurrence of which metal atoms and/or impurities diffuse) from the base layer BS to the semiconductor pattern or the conductive (e.g., electrically conductive) pattern.

The buffer layer BFL may be an inorganic film. The buffer layer BFL may include at least one selected from among silicon oxide, silicon nitride, and/or silicon oxynitride. For example, the buffer layer BFL may include a structure in which a silicon oxide layer and a silicon nitride layer are alternately stacked. In one or more embodiments of the present disclosure, the buffer layer BFL may not be provided.

The shielding electrode BML may be disposed or provided on the buffer layer BFL. The shielding electrode BML may overlap the transistor TR. In one or more embodiments of the present disclosure, the shielding electrode BML may also be disposed or provided below the signal transmission region SCL. The shielding electrode BML may protect the conductive (e.g., electrically conductive) pattern or the semiconductor pattern, such as the transistor TR and the signal transmission region SCL, by blocking light incident (or by reducing a degree or occurrence of light incident) from the lower portion of the display panel DP to the transistor TR or the signal transmission region SCL. The shielding electrode BML may include a conductive (e.g., electrically conductive) material. If (e.g., when) a voltage is applied to the shielding electrode BML, the threshold voltage of the transistor TR disposed or provided on the shielding electrode BML may be maintained. Without being limited thereto, the shielding electrode BML may be a floating electrode. In one or more embodiments of the present disclosure, the shielding electrode BML may not be provided.

The circuit layer D-CL may include a plurality of insulating layers 10, 20, 30, 40, 50, and 60 that are sequentially stacked. The insulating layers 10, 20, 30, 40, 50, and 60 may be disposed or provided on the buffer layer BFL. The insulating layers 10, 20, 30, 40, 50, and 60 may be inorganic layers and/or organic layers. For example, in one or more embodiments of the present disclosure, the first insulating layer 10, the second insulating layer 20, the third insulating layer 30, and the fourth insulating layer 40 may include an inorganic film, and the fifth insulating layer and the sixth insulating layer may include an organic film. However, embodiments of the present disclosure are not limited thereto. In one or more embodiments, in the circuit layer D-CL, at least one selected from among the first insulating layer 10, the second insulating layer 20, the third insulating layer 30, the fourth insulating layer 40, the fifth insulating layer 50, and the sixth insulating layer 60 may not be provided, or the circuit layer D-CL may further include an additional insulating (e.g., electrically insulating) layer.

The first insulating layer 10 may be disposed or provided on the buffer layer BFL. The first insulating layer 10 may include an inorganic film. The first insulating layer 10 may also be referred to as a first inorganic film. For example, the first insulating layer 10 may be an inorganic film including at least one selected from among aluminum oxide, titanium oxide, silicon oxide, silicon nitride, silicon oxynitride, zirconium oxide, and/or hafnium oxide. The first insulating layer 10 may have a single-layer structure or a multi-layer structure. The first insulating layer 10 may have a structure in which a plurality of inorganic films are stacked.

In one or more embodiments, the first insulating layer 10 may further include an organic film in addition to the inorganic film. If (e.g., when) the first insulating layer 10 includes a structure in which the inorganic film and the organic film are stacked, the first insulating layer 10 may further include a buffer inorganic film disposed or provided between the inorganic film and the organic film adjacent to each other.

In one or more embodiments, the contents as described in the first insulating layer 10 may be substantially equally applied to the second insulating layer 20, the third insulating layer 30, and the fourth insulating layer 40 to be described herein. The second insulating layer 20, the third insulating layer 30, and the fourth insulating layer 40 may be respectively referred to as a second inorganic film, a third inorganic film, and a fourth inorganic film. Each of the second insulating layer 20, the third insulating layer 30, and the fourth insulating layer 40 may have a single-layer structure or a multi-layer structure. For example, each of the second insulating layer 20, the third insulating layer 30, and the fourth insulating layer 40 may independently include at least one selected from among silicon oxide, silicon nitride, and/or silicon oxynitride.

A semiconductor pattern may be disposed or provided on the circuit layer D-CL. The semiconductor pattern may include polysilicon. Without being limited thereto, however, the semiconductor pattern may include amorphous (e.g., non-crystalline) silicon and/or metal oxide. The semiconductor pattern may have different electrical properties depending on whether it is doped or not. The semiconductor pattern may include a first region having a high doping concentration and a second region having a low doping concentration. The first region may be doped with a negative type or kind dopant (e.g., an N-type or kind dopant) or a positive type or kind dopant (e.g., a P-type or kind dopant). A P-type or kind transistor may include the first region doped with a P-type or kind dopant.

The first region may have higher conductivity (e.g., electrical conductivity) than the second region and substantially serve as an electrode or signal line. The second region may substantially correspond to an active (or channel) of a transistor. For example, a portion of the semiconductor pattern may be an active of a transistor, another portion thereof may be a source or drain of a transistor, and still another portion thereof may be a conductive (e.g., electrically conductive) region.

Referring to FIG. 5, in one or more embodiments of the present disclosure, the transistor TR may be disposed or provided on the first insulating layer 10. In one or more embodiments, the transistor TR may be electrically connected to the light-emitting element LD. A source S-D, an active A-D, and a drain D-D of the transistor TR may be formed or provided from the semiconductor pattern. In one or more embodiments, FIG. 5 illustrates a portion of the signal transmission region SCL formed or provided from the semiconductor pattern. In one or more embodiments, the signal transmission region SCL may be connected to the drain D-D of the transistor TR on a plane (e.g., in plan view).

The second insulating layer 20 may cover the source S-D, the active A-D, the drain D-D, and the signal transmission region SCL of the transistor TR disposed or provided on the first insulating layer 10. A gate G-D of the transistor TR may be disposed or provided on the second insulating layer 20. The third insulating layer 30 may be disposed or provided on the second insulating layer 20 to cover the gate G-D. The upper electrode pattern EE may be disposed or provided on the third insulating layer 30. The fourth insulating layer 40 may be disposed or provided on the third insulating layer 30 to cover the upper electrode pattern EE.

A first connection electrode CNE1 may be disposed or provided on the fourth insulating layer 40. The first connection electrode CNE1 may be connected to the signal transmission region SCL through a contact hole CH1 that passes through the second insulating layer 20, the third insulating layer 30, and the fourth insulating layer 40. The fifth insulating layer 50 may be disposed or provided on the fourth insulating layer 40 to cover the first connection electrode CNE1. The fifth insulating layer 50 may be an organic layer. In the present disclosure, the fifth insulating layer 50 may be referred to as a “first intermediate insulating (e.g., electrically insulating) layer.”

A second connecting electrode CNE2 may be disposed or provided on the fifth insulating layer 50. The second connecting electrode CNE2 may be connected to the first connecting electrode CNE1 through a contact hole CH2 that passes through the fifth insulating layer 50. The sixth insulating layer 60 may be disposed or provided on the fifth insulating layer 50 to cover the second connecting electrode CNE2. The sixth insulating layer 60 may be an organic layer. In the present disclosure, the sixth organic layer 60 may be referred to as a “second intermediate insulating (e.g., electrically insulating) layer.”

Each of the fifth insulating layer 50 and the sixth insulating layer 60 may independently include at least one selected from among an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and/or a perylene-based resin.

The display element layer D-OL may be disposed or provided on the circuit layer D-CL. The display element layer D-OL may include a light-emitting element LD and a pixel defining film PDL. The light-emitting element LD may include a first electrode AE, a second electrode CE that is opposite to (e.g., facing) the first electrode AE, and a functional layer EL disposed or provided between the first electrode AE and the second electrode CE.

A light-emitting opening OH that exposes a portion of the upper surface of the first electrode AE may be defined in the pixel defining film PDL. A light-emitting region EA may be defined to correspond to the light-emitting opening OH.

The first electrode AE may be disposed or provided on the circuit layer D-CL. In one or more embodiments of the present disclosure, the first electrode AE may be disposed or provided on the sixth insulating layer 60 of the circuit layer D-CL. The first electrode AE may be connected to the second connection electrode CNE2 through a connection contact hole CH3 defined through the sixth insulating layer 60. Therefore, the first electrode AE may be electrically connected to the signal transmission region SCL through the first connection electrode CNE1 and the second connection electrode CNE2 and may be electrically connected to a corresponding circuit element. The first electrode AE may include a single-layer structure or a multi-layer structure.

The first electrode AE may be an anode or a cathode. In one or more embodiments, the first electrode AE may be a pixel electrode. The second electrode CE may be a cathode or an anode. The second electrode CE may be a common electrode. For example, if (e.g., when) the first electrode AE is an anode, the second electrode CE may be a cathode, and if (e.g., when) the first electrode AE is a cathode, the second electrode CE may be an anode.

The first electrode AE may be a transmissive electrode, a semi-transmissive electrode, or a reflective electrode. The first electrode AE may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), tungsten (W), or a compound or mixture thereof (e.g., a mixture of Ag and Mg). In one or more embodiments, the first electrode AE may have a multi-layer structure including: a reflective film or semi-transmissive film of the materials as described in one or more embodiments; and a transparent (e.g., substantially transparent) conductive (e.g., electrically conductive) film of indium tin oxide (ITO), indium zinc oxide (IZO), zinc oxide (e.g., ZnO), indium tin zinc oxide (ITZO), and/or the like. For example, the first electrode AE may have a three-layer structure of ITO/Ag/ITO, but embodiments of the present disclosure are not limited thereto. In one or more embodiments, the first electrode AE may include a metal material as described in one or more embodiments, a combination of two or more metal materials selected from among the metal materials as described in one or more embodiments, an oxide of the metal materials as described in one or more embodiments, and/or the like.

The second electrode CE may be a transmissive electrode, a semi-transmissive electrode, or a reflective electrode. If (e.g., when) the second electrode CE is a transmissive electrode, the second electrode CE may be composed of a transparent (e.g., substantially transparent) metal oxide, such as indium tin oxide (ITO), indium zinc oxide (IZO), zinc oxide (e.g., ZnO), and indium tin zinc oxide (ITZO). In one or more embodiments, the second electrode CE may be formed or provided by including Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg).

The functional layer EL may include a light-emitting layer. The light-emitting layer may include a light-emitting material, such as an organic material and/or a quantum dot. The functional layer EL including the light-emitting layer may emit light of at least one color selected from among blue, red, and green in each separate pixel. In one or more embodiments, the functional layer EL may provide blue light throughout the active region DM-AA (see FIG. 4).

The functional layer EL may further include a hole control layer and an electron control layer in addition to the light-emitting layer. The hole control layer may be disposed or provided between the first electrode AE and the light-emitting layer, and the electron control layer may be disposed or provided between the light-emitting layer and the second electrode CE.

The light-emitting layer of the functional layer EL may be patterned and then provided so as to correspond to the light-emitting region EA. In one or more embodiments, the hole control layer and the electron control layer of the functional layer EL may be formed or provided in common for a plurality of pixels PX (see FIG. 4). For example, the hole control layer and the electron control layer may be provided as a common layer for the entire pixels PX (see FIG. 4). However, embodiments of the present disclosure are not limited thereto, and the hole control layer and the electron control layer may be patterned and then provided so as to correspond to the light-emitting region EA or may be provided in a form in which they overlap the pixel defining film PDL and a portion thereof is disconnected.

In one or more embodiments of the present disclosure, the pixel defining film PDL may have a single-layer structure or a multi-layer structure. The pixel defining film PDL may be of a polymer resin. For example, the pixel defining film PDL may be formed or provided by including a polyacrylate-based resin and/or a polyimide-based resin. In one or more embodiments, the pixel defining film PDL may be formed or provided by further including an inorganic material in addition to the polymer resin. In one or more embodiments, the pixel defining film PDL may be formed or provided by including a light absorbing material and/or by including a black pigment and/or a black dye. The pixel defining film PDL formed or provided by including the black pigment and/or the black dye may implement a black pixel defining film. If (e.g., when) forming or providing the pixel defining film PDL, carbon black and/or the like may be used as the black pigment and/or the black dye, but embodiments of the present disclosure are not limited thereto.

In one or more embodiments, the pixel defining film PDL may be of an inorganic material. For example, the pixel defining film PDL may be of an inorganic material, such as silicon nitride (e.g., Si₃N₄ or SiNₓ, wherein 0<X≤2), silicon oxide (e.g., SiOₓ, wherein 0<X≤2; e.g., SiO₂), and/or silicon oxynitride (e.g., Si₂N₂O or SiOₓN_{y}, wherein 0<X≤2 and 0≤Y≤2; e.g., SiON).

The encapsulation layer ECL may be disposed or provided on the second electrode CE of the light-emitting element LD. The encapsulation layer ECL may cover the light-emitting element LD. In one or more embodiments of the present disclosure, the encapsulation layer ECL may be disposed or provided on the dam pattern DMP and the grooves GV1, GV2, and GV3 in the hole region HA of the display module EDM.

The encapsulation layer ECL may include a plurality of encapsulation films. The encapsulation layer ECL may include at least one inorganic film. In one or more embodiments, the encapsulation layer ECL may further include at least one organic film. In one or more embodiments of the present disclosure, the encapsulation layer ECL may include a first inorganic layer IOL1, an organic layer OL, and a second inorganic layer IOL2 sequentially stacked in the third direction DR3. However, embodiments of the present disclosure are not limited thereto, and the number of stacked layers of the encapsulation layer ECL may vary. The first inorganic layer IOL1 and the second inorganic layer IOL2 may protect the display element layer D-OL from moisture and/or oxygen, and the organic layer OL may protect the display element layer D-OL from foreign substances, such as dust particles.

The input sensor ISL may be disposed or provided on the display panel DP. The input sensor ISL may be disposed or provided directly on the encapsulation layer ECL. The input sensor ISL may be disposed or provided directly on the second inorganic layer IOL2. The input sensor ISL may include a sensor base layer 210, a first sensor conductive layer 220, a sensor insulating layer 230, a second sensor conductive layer 240, and a sensor cover layer 250.

The sensor base layer 210 may be disposed or provided directly on the display panel DP. The sensor base layer 210 may be an inorganic layer including at least any one selected from among silicon nitride, silicon oxynitride, and/or silicon oxide. In one or more embodiments, the sensor base layer 210 may be an organic layer including an epoxy resin, an acrylic resin, and/or an imide-based resin. The sensor base layer 210 may have a single-layer structure or a multi-layer structure in which layers are stacked along the third direction DR3.

Each of the first sensor conductive layer 220 and the second sensor conductive layer 240 may have a single-layer structure or a multi-layer structure in which layers are stacked along the third direction DR3.

A single-layered conductive (e.g., electrically conductive) layer may include a metal layer and/or a transparent (e.g., substantially transparent) conductive (e.g., electrically conductive) layer. The metal layer may include molybdenum, silver, titanium, copper, aluminum, or an alloy thereof. The transparent conductive layer may include a transparent (e.g., substantially transparent) conductive (e.g., electrically conductive) oxide, such as indium tin oxide, indium zinc oxide, zinc oxide, and/or indium zinc tin oxide. In one or more embodiments, the transparent conductive layer may include a conductive (e.g., electrically conductive) polymer, such as poly(3,4-ethylenedioxythiophene) (PEDOT), metal nanowire, graphene, and/or the like.

A multi-layered conductive (e.g., electrically conductive) layer may include metal layers. For example, the metal layers may have a three-layer structure of titanium/aluminum/titanium. The multi-layered conductive layer may include at least one metal layer and at least one transparent (e.g., substantially transparent) conductive (e.g., electrically conductive) layer.

The sensor insulating layer 230 may be disposed or provided between the first sensor conductive layer 220 and the second sensor conductive layer 240. The sensor cover layer 250 may be disposed or provided on the sensor insulating layer 230 and cover the second sensor conductive layer 240. The second sensor conductive layer 240 may include a conductive (e.g., electrically conductive) pattern. The sensor cover layer 250 may cover the conductive (e.g., electrically conductive) pattern and reduce or eliminate the probability of damage to the conductive (e.g., electrically conductive) pattern in a subsequent process.

Each of the sensor insulating layer 230 and the sensor cover layer 250 may include an inorganic film. The inorganic film may include at least one selected from among aluminum oxide, titanium oxide, silicon oxide, silicon nitride, silicon oxynitride, zirconium oxide, and/or hafnium oxide.

In one or more embodiments, each of the sensor insulating layer 230 and the sensor cover layer 250 may include an organic film. The organic film may include at least one selected from among an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, and/or a perylene-based resin.

Referring to FIGS. 4 and 6, a module hole HH may be defined in the display module DM, and the display module DM may include a hole region HA including the module hole HH formed or provided by passing through the display module DM. The module hole HH may be formed or provided by passing through the display module DM and defined by a side wall DM-HS of the exposed display module DM.

The display module DM may include a plurality of dam portions DM1, DM2, and DM3 disposed or provided in the hole region HA. The dam portions DM1, DM2, and DM3 may protect the display element layer D-OL and/or the like during a process of forming or providing the module hole HH. For example, the dam portions DM1, DM2, and DM3 may prevent physical impacts, such as cracks, which may occur if (e.g., when) the module hole HH is formed or provided, from being transmitted to the display region AA (or reduce a degree to or occurrence of which physical impacts, such as cracks, which may occur if (e.g., when) the module hole HH is formed or provided, are transmitted to the display region AA). In one or more embodiments, the dam portions DM1, DM2, and DM3 may prevent chemical materials and/or the like used in the processing of the display module DM, such as the formation of the module hole HH, from penetrating into the display region AA (or reduce a degree to or occurrence of which chemical materials and/or the like used in the processing of the display module DM, such as the formation of the module hole HH, penetrate into the display region AA). In one or more embodiments, if (e.g., when) an excessive amount of resin composition and/or the like is provided during the formation of the organic layer OL and/or the like of the encapsulation layer ECL, the dam portions DM1, DM2, and DM3 may also function to prevent the resin composition from flowing (or reduce a degree to or occurrence of which the resin composition flows).

In one or more embodiments, in FIGS. 4 and 6, three dam portions DM1, DM2, and DM3 are illustrated as being disposed or provided, but embodiments of the present disclosure are not limited thereto. The number of dam portions may be between two and four.

The dam portions DM1, DM2, and DM3 may be disposed or provided on the base layer BS. In one or more embodiments of the present disclosure, the dam portions DM1, DM2, and DM3 may be disposed or provided on a lower insulating layer LIL. The lower insulating layer LIL may include the first insulating layer 10, the second insulating layer 20, the third insulating layer 30, and the fourth insulating layer 40 as described in FIG. 5. In one or more embodiments, the fourth insulating layer 40 disposed or provided on the uppermost portion of the lower insulating layer LIL may be described as a “first lower insulating (e.g., electrically insulating) layer.”

In one or more embodiments of the present disclosure, a first dam portion DM1 disposed or provided to be around (e.g., surround) the module hole HH and a second dam portion DM2 disposed or provided to be around (e.g., surround) the first dam portion DM1 may be included. In one or more embodiments, the display module DM may further include a third dam portion DM3 around (e.g., surrounding) the second dam portion DM2 and adjacent to the display region AA.

The grooves GV1, GV2, and GV3 may be defined between the dam portions DM1, DM2, and DM3. A first groove GV1 may be defined between the first dam portion DM1 and the second dam portion DM2, and a second groove GV2 may be defined between the second dam portion DM2 and the third dam portion DM3. In the display module DM according to one or more embodiments of the present disclosure as illustrated in FIG. 6, a third groove GV3 may be defined between the third dam portion DM3 and a portion of the display panel DP at the boundary between the display region AA and the hole region HA.

Each of the dam portions DM1, DM2, and DM3 may include a plurality of dam layers stacked in the third direction DR3 which is the thickness direction. Each of the first dam portion DM1 and the second dam portion DM2 may include a first dam layer DM1-B and DM2-B and a second dam layer DM1-T and DM2-T. The second dam layer DM1-T and DM2-T may be disposed or provided on the first dam layer DM1-B and DM2-B.

The first dam layer DM1-B and DM2-B may be disposed or provided on substantially the same layer as the fifth insulating layer 50, and the second dam layer DM1-T and DM2-T may be disposed or provided on substantially the same layer as the sixth insulating layer 60. For example, the first dam layer DM1-B and DM2-B may be formed or provided in substantially the same process step as the fifth insulating layer 50, and the second dam layer DM1-T and DM2-T may be formed or provided in substantially the same process step as the sixth insulating layer 60. For example, in one or more embodiments of the present disclosure, the first dam layer DM1-B and DM2-B may be an organic layer of substantially the same material as the fifth insulating layer 50, and the second dam layer DM1-T and DM2-T may be an organic layer of substantially the same material as the sixth insulating layer 60. However, embodiments of the present disclosure are not limited thereto.

In FIG. 6 and/or the like, each of the first dam portion DM1 and the second dam portion DM2 is illustrated as including two dam layers, but embodiments of the present disclosure are not limited thereto, and at least one selected from the first dam portion DM1 or the second dam portion DM2 may include three dam layers or may include only one dam layer.

In one or more embodiments, the third dam portion DM3 may include a first dam layer DM3-B, a second dam layer DM3-T, and a third dam layer DM3-A stacked in the third direction DR3. In the third dam portion DM3, the first dam layer DM3-B may be formed or provided in substantially the same process step as the fifth insulating layer 50, the second dam layer DM3-T may be formed or provided in substantially the same process step as the sixth insulating layer 60, and the third dam layer DM3-A may be formed or provided in substantially the same process step as the pixel defining film PDL. However, embodiments of the present disclosure are not limited thereto.

In one or more embodiments of the present disclosure, each of the first dam layer DM1-B, DM2-B, and DM3-B and the second dam layer DM1-T, DM2-T, and DM3-T may have an inclined side surface. However, embodiments of the present disclosure are not limited thereto, and at least portions of the first dam layer DM1-B, DM2-B, and DM3-B and the second dam layer DM1-T, DM2-T, and DM3-T may be formed or provided to include a side surface having a curved shape.

The circuit layer D-CL may further include a protrusion pattern MTP. The protrusion pattern MTP may be disposed or provided on at least one or more of the dam portions DM1, DM2, and DM3. The protrusion pattern MTP may be disposed or provided on the first dam layer DM1-B, DM2-B, and DM3-B. The protrusion pattern MTP may be disposed or provided between the first dam layer DM1-B, DM2-B, and DM3-B and the second dam layer DM1-T, DM2-T, and DM3-T. The protrusion pattern MTP may be disposed or provided on the first dam layer DM1-B, DM2-B, and DM3-B and have a width greater than the width of the first dam layer DM1-B, DM2-B, and DM3-B in one direction by including a protruding portion.

The protrusion pattern MTP may be formed or provided in substantially the same process as any one selected from among the conductive (e.g., electrically conductive) patterns of the circuit layer D-CL disposed or provided in the display region AA. For example, the protrusion pattern MTP may be formed or provided in substantially the same process step as the second connection electrode CNE2. For example, the protrusion pattern MTP may be of substantially the same material as the second connection electrode CNE2. However, embodiments of the present disclosure are not limited thereto.

The display module DM may further include inorganic dams IOP disposed or provided in the hole region HA. In FIG. 6, two inorganic dams IOP disposed or provided adjacent to the module hole HH portion are illustrated, but embodiments of the present disclosure are not limited thereto, and at least one of the inorganic dams IOP may not be provided, or more inorganic dams may be disposed or provided.

In one or more embodiments of the present disclosure, each of the inorganic dams IOP may include a first layer IL1 and a second layer IL2. The first layer IL1 may include substantially the same material as the first insulating layer 10 and be formed or provided through substantially the same process as the first insulating layer 10. The second layer IL2 may include substantially the same material as the second insulating layer 20 and be formed or provided through substantially the same process as the second insulating layer 20. However, this is only an example, and the composition of the layers that constitutes each of the inorganic dams IOP may be suitably modified. The width of the first layer IL1 may be greater than the width of the second layer IL2. In one or more embodiments of the present disclosure, each of the inorganic dams IOP may have a stepped shape (e.g., a substantially stepped shape).

Referring to FIGS. 5 and 6, the encapsulation layer ECL may cover the components of the display element layer D-OL and the exposed circuit layer D-CL. In the display region AA, the encapsulation layer ECL may cover the light-emitting element LD and the pixel defining film PDL, and in the hole region HA, the encapsulation layer ECL may cover an exposed portion of the circuit layer D-CL, the dam portions DM1, DM2, and DM3, and the grooves GV1, GV2, and GV3 defined between the dam portions DM1, DM2, and DM3. The encapsulation layer ECL includes at least a first inorganic layer IOL1.

The first inorganic layer IOL1 may be disposed or provided on the second electrode CE. The first inorganic layer IOL1 may be disposed or provided on the dam portions DM1, DM2, and DM3, a portion of the protrusion pattern MTP, and the grooves GV1, GV2, and GV3. The first inorganic layer IOL1 may cover the exposed surfaces of the dam portions DM1, DM2, and DM3, a portion of the protrusion pattern MTP, and the grooves GV1, GV2, and GV3. The first inorganic layer IOL1 may protect the components of the display panel DP from moisture, oxygen, and/or the like outside the display panel DP.

The first inorganic layer IOL1 may include a plurality of sub-layers. The first inorganic layer IOL1 may be formed or provided by two different methods and include the plurality of sub-layers that are distinguished by density. The first inorganic layer IOL1 may include silicon nitride. The first inorganic layer IOL1 may be formed or provided by sequentially performing a first method selected from among a plasma-enhanced atomic layer deposition (PEALD) method, a sputtering method, and an electron beam evaporator method and a second method which is a plasma-enhanced chemical vapor deposition (PECVD) method. The descriptions of the plurality of sub-layers included in the first inorganic layer IOL1 will be provided herein in more detail.

The encapsulation layer ECL may further include an organic layer OL disposed or provided on the first inorganic layer IOL1 and a second inorganic layer IOL2 disposed or provided on the organic layer OL.

The organic layer OL may be disposed or provided on the first inorganic layer IOL1 and overlap at least one or more of the first groove GV1, the second groove GV2, and the third groove GV3. For example, the organic layer OL may overlap the third groove GV3. The organic layer OL may not overlap the first groove GV1 and the second groove GV2.

The second inorganic layer IOL2 may be disposed or provided on the organic layer OL and cover all (e.g., substantially all) of the first groove GV1, the second groove GV2, and the third groove GV3. In a portion of the hole region HA, the second inorganic layer IOL2 may be disposed or provided directly on the first inorganic layer IOL1. In a region that corresponds to the first groove GV1 and the second groove GV2 in which the organic layer OL is not disposed, the second inorganic layer IOL2 may be in contact with the upper surface of the first inorganic layer IOL1.

Each of FIGS. 7 to 9 is an enlarged cross-sectional view of a portion of the display module according to one or more embodiments of the present disclosure. FIG. 7 is an enlarged cross-sectional view of region AA′ of FIG. 6. FIG. 8 is an enlarged cross-sectional view of region BB′ of FIG. 7. FIG. 9 is a cross-sectional view schematically illustrating the more detailed layer configuration or arrangement of the first inorganic layer IOL1 as illustrated in FIGS. 6 and 7.

Referring to FIGS. 6 and 7, the circuit layer D-CL may include a protrusion pattern MTP including a tip portion TP that protrudes from the dam portions DM1, DM2, and DM3. The tip portion TP may protrude in the inward direction of the grooves GV1, GV2, and GV3. The protrusion pattern MTP may entirely (e.g., substantially entirely) overlap the second dam layer DM1-T, DM2-T, and DM3-T and have a width greater than the width of one surface of an adjacent dam layer in one direction. In one or more embodiments, the protrusion pattern MTP may not entirely overlap the second dam layer DM1-T, DM2-T, and DM3-T and may be provided as two separated portions on a cross section so as to be adjacent to the edge of the second dam layer DM1-T, DM2-T, and DM3-T adjacent to the grooves GV1, GV2, and GV3. In one or more embodiments, the shape of the protrusion pattern MTP may be provided in one or more suitable forms according to the shapes of the provided dam portions DM1, DM2, and DM3, the patterning methods of the dam portions DM1, DM2, and DM3, or the patterning processes of the dam portions DM1, DM2, and DM3.

Because the protrusion pattern MTP is disposed or provided to protrude further inward into the groove GV1 than the upper surface of the first dam layer DM1-B and DM2-B and the lower surface of the second dam layer DM1-T and DM2-T so as to have a tip portion TP, the dam portions DM1 and DM2 may include an undercut UCP portion.

The first groove GV1 and the second groove GV2 may be defined between two neighboring dam portions DM1, DM2, and DM3, and the first groove GV1 may include a first recessed portion GV-B defined by the first dam layer DM1-B and DM2-B and a second recessed portion GV-T defined by the second dam layer DM1-T and DM2-T. The second recessed portion GV-T may overlap and be defined on the first recessed portion GV-B. The first groove GV1 may be defined between the first dam portion DM1 and the second dam portion DM2, and the second groove GV2 may be defined between the second dam portion DM2 and the third dam portion DM3. The third groove GV3 may be defined between the third dam portion DM3 and each of the fifth insulating layer 50 and the sixth organic layer 60.

Each of the dam portions DM1, DM2, and DM3 may include inclined surfaces IS1 and IS2 that define a groove GV. The dam portions DM1, DM2, and DM3 may include a first inclined surface IS1 and a second inclined surface IS2. As illustrated in FIG. 7, the first dam layer DM1-B and DM2-B may include the first inclined surface IS1 that defines a first recessed portion GV-B, and the second dam layer DM1-T and DM2-T may include the second inclined surface IS2 that defines a second recessed portion GV-T.

The first inorganic layer IOL1 may be disposed or provided to cover all (e.g., substantially all) of the upper surface of the fourth insulating layer 40 exposed in the groove GV, the first inclined surface IS1 which is the side surface of the first dam layer DM1-B and DM2-B, the tip portion TP of the conductive (e.g., electrically conductive) pattern, the second inclined surface IS2 which is the side surface of the second dam layer DM1-T and DM2-T, and the upper surface of the second dam layer DM1-T and DM2-T. The first inorganic layer IOL1 may be in contact with each of the upper surface of the fourth insulating layer 40, the first inclined surface IS1, and the tip portion TP of the conductive (e.g., electrically conductive) pattern.

Referring to FIGS. 6 to 8 together, a portion of the first inorganic layer IOL1 disposed or provided around the tip portion TP may not have a uniform (e.g., substantially uniform) thickness due to the undercut UCP structure, and a portion thereof may have a thickness smaller than that of the other portions.

The first inorganic layer IOL1 may include a first portion IOL1-1 disposed or provided on an upper surface MTP-U of the tip portion TP of the protrusion pattern MTP, a second portion IOL1-2 disposed or provided on a lower surface MTP-B of the tip portion TP, and a third portion IOL1-3 disposed or provided on the first inclined surface IS1. The first inorganic layer IOL1 may further include a fourth portion IOL1-4 disposed or provided on a side surface MTP-S of the tip portion TP. The first portion IOL1-1 to the fourth portion IOL1-4 may have an integrated shape (e.g., a substantially integrated shape), but may have different thicknesses. By the first portion IOL1-1 to the fourth portion IOL1-4, the first inorganic layer IOL1 may entirely (e.g., substantially entirely) cover each of the upper surface MTP-U, the lower surface MTP-B, and the side surface MTP-S of the tip portion TP, and the first inclined surface IS1 of the first dam layer DM1-B and DM2-B.

In the first inorganic layer IOL1 according to one or more embodiments of the present disclosure, the first portion IOL1-1 disposed or provided on the upper surface MTP-U of the tip portion TP may have a thickness greater than that of the other portions. A thickness T2 of the second portion IOL1-2 disposed or provided on the lower surface MTP-B of the tip portion TP may be about 30% or more of a thickness T1 of the first portion IOL1-1. The thickness T2 of the second portion IOL1-2 may be about 30% to about 60% of the thickness T1 of the first portion IOL1-1. A thickness T3 of the third portion IOL1-3 disposed or provided on the first inclined surface IS1 may be about 40% or more of the thickness T1 of the first portion IOL1-1. The thickness T3 of the third portion IOL1-3 may be about 40% to about 70% of the thickness T1 of the first portion IOL1-1. A thickness T4 of the fourth portion IOL1-4 disposed or provided on the side surface MTP-S of the tip TP may be about 60% or more of the thickness T1 of the first portion IOL1-1. The thickness T4 of the fourth portion IOL1-4 may be about 60% to about 90% of the thickness T1 of the first portion IOL1-1.

The display module DM according to one or more embodiments of the present disclosure may include a structure of the dam portions DM1, DM2, and DM3 and the grooves GV1, GV2, and GV3 adjacent to the module hole HH and may also include the dam portions DM1, DM2, and DM3 and the protrusion pattern MTP including a tip portion TP that protrudes from the dam portions DM1, DM2, and DM3. Because the protrusion pattern MTP has the tip portion TP, the dam portions DM1, DM2, and DM3 may have an undercut UCP structure, and if (e.g., when) the thickness of the first inorganic layer IOL1 in the undercut UCP portion becomes thin, moisture and/or oxygen may relatively easily penetrate into the thin portion of the first inorganic layer IOL1. Accordingly, defects, such as oxidation of the components included in the circuit layer D-CL and the display element layer D-OL of the display module DM, may occur.

In the display module DM according to one or more embodiments of the present disclosure, by providing the thickness of the first inorganic layer IOL1 in the undercut UCP portion to be a set or predetermined thickness or more, the reliability of the display module DM may be improved or enhanced. For example, in the display module DM according to one or more embodiments of the present disclosure, with respect to the first portion IOL1-1 disposed or provided on the upper surface MTP-U of the tip portion TP, by providing the second portion IOL1-2 disposed or provided on the lower surface MTP-B of the tip portion TP with a thickness that is about 30% or more of the thickness of the first portion IOL1-1 and providing the third portion IOL1-3 disposed or provided on the first inclined surface IS1 with a thickness that is about 40% or more of the thickness of the first portion IOL1-1, it may be feasible to prevent moisture and/or oxygen from penetrating (or reduce a degree to or occurrence of which moisture and/or oxygen penetrate) into the thin portion of the first inorganic layer IOL1, thereby preventing defects (or reducing a degree or occurrence of defects).

FIG. 9 is an enlarged cross-sectional view schematically illustrating the more detailed layer configuration or arrangement of the first inorganic layer IOL1. The first inorganic layer IOL1 as illustrated in FIG. 9 may be any one selected from among the portions of the first inorganic layer IOL1 as illustrated in FIG. 8. For example, FIG. 9 may be any one selected from among the first portion IOL1-1, the second portion IOL1-2, the third portion IOL1-3, and the fourth portion IOL1-4 of the first inorganic layer IOL1 as illustrated in FIG. 8.

Referring to FIG. 8 and FIG. 9 together, a bottom layer BSL may be a member that provides a bottom surface BSF on which the first inorganic layer IOL1 is disposed or provided. In the first portion IOL1-1 of the first inorganic layer IOL1, the bottom surface BSF may be the upper surface MTP-U of the tip portion TP. In the second portion IOL1-2 of the first inorganic layer IOL1, the bottom surface BSF may be the lower surface MTP-B of the tip portion TP. In the third portion IOL1-3 of the first inorganic layer IOL1, the bottom surface BSF may be the first inclined surface IS1. In the fourth portion IOL1-4 of the first inorganic layer IOL1, the bottom surface BSF may be the side surface MTP-S of the tip portion TP.

In one or more embodiments of the present disclosure, the first inorganic layer IOL1 may include a plurality of sub-layers that include substantially the same material, but have different densities. The first inorganic layer IOL1 may include a first sub-layer IL-S1 disposed or provided on the bottom layer BSL, a second sub-layer IL-S2 disposed or provided on the first sub-layer IL-S1, and a third sub-layer IL-S3 disposed or provided on the second sub-layer IL-S2. As the first inorganic layer IOL1 has a structure including a plurality of sub-layers, as described in one or more embodiments, the display module DM may provide the thickness of the first inorganic layer IOL1 in the undercut UCP portion to be a set or predetermined thickness or more.

The first sub-layer IL-S1 may be disposed or provided directly on the bottom surface BSF. The first sub-layer IL-S1 may have a relatively high density. The second sub-layer IL-S2 may be disposed or provided directly on the first sub-layer IL-S1 and have a relatively low density. The third sub-layer IL-S3 may be disposed or provided directly on the second sub-layer IL-S2 and have a relatively high density. In the first inorganic layer IOL1 according to one or more embodiments of the present disclosure, the second sub-layer IL-S2 disposed or provided in the middle may have a lower density than the first sub-layer IL-S1 and the third sub-layer IL-S3 adjacent thereto. The density difference between the second sub-layer IL-S2 and the first sub-layer IL-S1 may be about 0.1 g/cm³ or more.

Each of the first sub-layer IL-S1, the second sub-layer IL-S2, and the third sub-layer IL-S3 may include silicon nitride. Each of the first sub-layer IL-S1, the second sub-layer IL-S2, and the third sub-layer IL-S3 may be formed or provided from substantially the same Si—N precursor.

In one or more embodiments of the present disclosure, the density of a portion of the first inorganic layer IOL1 may increase in a direction away from the bottom layer BSL. In the second sub-layer IL-S2 and the third sub-layer IL-S3 of the first inorganic layer IOL1, the density of silicon nitride may gradually increase in a direction away from the first sub-layer IL-S1. In one or more embodiments, the density of silicon nitride within a specific (e.g., set or predetermined) thickness range may be similar, and the density of silicon nitride outside the specific (e.g., set or predetermined) thickness range may be gradually changed so as to be distinguishable from the density within the specific (e.g., set or predetermined) thickness range.

The first sub-layer IL-S1 may be derived from a preliminary first inorganic layer PIL (see FIG. 11A) formed or provided by the first method as described in one or more embodiments. The second sub-layer IL-S2 and the third sub-layer IL-S3 may be formed or provided by the second method as described in one or more embodiments.

A thickness d2 of the first sub-layer IL-S1 may be about 0.1% to about 10% of a total thickness d1 of the first inorganic layer IOL1. For example, the thickness d2 of the first sub-layer IL-S1 may be about 0.1% to about 1% of the total thickness d1 of the first inorganic layer IOL1. The total thickness d1 of the first inorganic layer IOL1 may be about 1,000 Å to about 20,000 Å.

The first inorganic layer IOL1 may have a refractive index of about 1.7 to about 2.0 at a wavelength of about 550 nm. For example, the first inorganic layer IOL1 may have a refractive index of about 1.85 to about 1.9 at a wavelength of about 550 nm. Each of the first sub-layer IL-S1, the second sub-layer IL-S2, and the third sub-layer IL-S3 included in the first inorganic layer IOL1 may have different refractive indices due to differences in density. For example, the refractive index of the second sub-layer IL-S2 having a low density may be lower than the refractive index of each of the first sub-layer IL-S1 and the third sub-layer IL-S3 having a high density.

The electronic device according to one or more embodiments of the present disclosure including the first inorganic layer IOL1 may exhibit excellent or suitable reliability characteristics. The first inorganic layer IOL1 may have a low water vapor transmission rate (WVTR) due to a structure including the two or more sub-layers as described in one or more embodiments. The water vapor transmission rate of the first inorganic layer IOL1 may be about 1.0×10⁻⁴ g/(m²·day) or less. For example, the water vapor transmission rate of the first inorganic layer IOL1 may be about 5.0×10⁻⁵ g/(m²·day) or less. The first inorganic layer IOL1 may include a structure in which the first sub-layer IL-S1, second sub-layer IL-S2, and third sub-layer IL-S3, as described in one or more embodiments, are stacked, and the first sub-layer IL-S1 adjacent to the bottom surface BSF may have a low water vapor transmission rate as it has a high density.

Each of FIGS. 10A to 10C schematically illustrates one step of a method for manufacturing an electronic device according to one or more embodiments of the present disclosure. Each of FIGS. 11A and 11B is an enlarged cross-sectional view of a portion of a display module in one step of the method for manufacturing the electronic device according to one or more embodiments of the present disclosure. FIG. 12 is an enlarged cross-sectional view of a portion of the display module in one step of the method for manufacturing the electronic device according to one or more embodiments of the present disclosure. Each of FIGS. 10A to 10C schematically illustrates one step of a process for manufacturing the display module in a cross section that corresponds to FIG. 7. Each of FIGS. 11A and 11B schematically illustrates one step of a process for manufacturing the first inorganic layer in a cross section that corresponds to FIG. 9. FIG. 12 schematically illustrates one step of the process for manufacturing the first inorganic layer in a cross section that corresponds to FIG. 8.

Hereinafter, the method for manufacturing the electronic device according to one or more embodiments of the present disclosure will be described in more detail with reference to FIGS. 10A to 12.

The method for manufacturing the electronic device according to one or more embodiments of the present disclosure may include providing a base layer, forming or providing a circuit layer, forming or providing a display element layer, and forming or providing an encapsulation layer. The forming or providing of the encapsulation layer may include forming or providing a first inorganic layer. In the descriptions of the method for manufacturing the electronic device according to one or more embodiments of the present disclosure, substantially the same descriptions may be applied to substantially the same components as those of the electronic device as described with reference to FIGS. 1 to 9.

FIGS. 10A to 10C sequentially illustrate forming or providing the first dam portion DM1 and the second dam portion DM2 (see FIG. 6) on the lower insulating layers 30 and 40 and forming or providing the first inorganic layer IOL1 in a state in which the first groove GV1 (see FIG. 7) is provided between the first dam portion DM1 and the second dam portion DM2.

Referring to FIGS. 10A to 10C, the forming or providing of the first inorganic layer IOL1 may include applying a first deposition material EM1 to form or provide a preliminary first inorganic layer PIL and applying a second deposition material EM2 on the preliminary first inorganic layer PIL to form or provide the first inorganic layer IOL1. In the present disclosure, the first deposition material EM1 may be provided by the first method, and the second deposition material EM2 may be provided by the second method different from the first method.

The first deposition material EM1 may be provided by the first method selected from among a plasma-enhanced atomic layer deposition (PEALD) method, a sputtering method, and an electron beam evaporator method. For example, the first deposition material EM1 may be provided by the plasma-enhanced atomic layer deposition (PEALD) method. The preliminary first inorganic layer PIL formed or provided by the first deposition material EM1 may be formed or provided to cover all (e.g., substantially all) of the upper surface of the fourth insulating layer 40, the first inclined surface IS1 which is the side surface of the first dam layer DM1-B and DM2-B, the tip portion TP of the conductive (e.g., electrically conductive) pattern, the second inclined surface IS2 which is the side surface of the second dam layer DM1-T and DM2-T, and the upper surface of the second dam layer DM1-T and DM2-T.

The second deposition material EM2 may be provided by a method different from the first method. The second deposition material EM2 may be provided by the second method which is a plasma-enhanced chemical vapor deposition (PECVD) method. As the second deposition material EM2 is provided, an additional stacked structure may be formed or provided on the previously formed or provided preliminary first inorganic layer PIL, thereby forming or providing the first inorganic layer IOL1. The first inorganic layer IOL1 may be formed or provided to cover all (e.g., substantially all) of the upper surface of the fourth insulating layer 40, the first inclined surface IS1 which is the side surface of the first dam layer DM1-B and DM2-B, the tip portion TP of the conductive (e.g., electrically conductive) pattern, the second inclined surface IS2 which is the side surface of the second dam layer DM1-T and DM2-T, and the upper surface of the second dam layer DM1-T and DM2-T.

Referring to FIGS. 10A to 10C and FIGS. 11A and 11B, after the preliminary first inorganic layer PIL is formed or provided by the first deposition material EM1 on the bottom layer BSL, the second deposition material EM2 may be provided on the preliminary first inorganic layer PIL to form or provide the first inorganic layer IOL1. Among the first inorganic layer IOL1, the first sub-layer IL-S1 may correspond to the preliminary first inorganic layer PIL, and the second sub-layer IL-S2 and the third sub-layer IL-S3 may be formed or provided by providing the second deposition material EM2. For example, the first sub-layer IL-S1 may be formed or provided by providing a portion of the second deposition material EM2 on the preliminary first inorganic layer PIL by a plasma-enhanced chemical vapor deposition (PECVD) method, and the remainder of the second deposition material EM2 may be provided on the first sub-layer IL-S1 to form or provide the second sub-layer IL-S2 and the third sub-layer IL-S3 that are sequentially stacked. In one or more embodiments, the bottom layer BSL may be a member that provides a bottom surface BSF on which the first inorganic layer IOL1 is disposed or provided.

Because the first sub-layer IL-S1 corresponds to the preliminary first inorganic layer PIL, the thickness d2 of the first sub-layer IL-S1 may be substantially the same as a thickness d-p of the preliminary first inorganic layer PIL. In one or more embodiments, thicknesses and/or the like being “substantially the same” may include not only a case in which they are physically substantially the same, but also a case in which there is a difference due to process errors that occur despite substantially the same design. The thickness d-p of the preliminary first inorganic layer PIL may be about 0.1% to about 10% of the total thickness d1 of the first inorganic layer IOL1. For example, the thickness d-p of the preliminary first inorganic layer PIL may be about 0.1% to about 1% of the total thickness d1 of the first inorganic layer IOL1. The total thickness d1 of the first inorganic layer IOL1 may be about 1,000 Å to about 20,000 Å.

The first deposition material EM1 and the second deposition material EM2 may include substantially the same material as each other. Each of the first deposition material EM1 and the second deposition material EM2 may include a precursor material to form or provide a silicon nitride film. Each of the first deposition material EM1 and the second deposition material EM2 may include an aminosilane material having Si—N as a core structure. For example, each of the first deposition material EM1 and the second deposition material EM2 may include at least one selected from among cyclosilizane, trisilyamine, bis(diethylamino)silane, bis(t-butylamino)silane, tris(dimethylamino)silane, tris(isopropylamino)silane, tetrakis(dimethylamino)silane, tri(isopropyl)cyclotrisilazane, and/or tetramethyldisilazane. Without being limited thereto, however, each of the first deposition material EM1 and the second deposition material EM2 may include, without limitation, any suitable precursor material as long as it is capable of forming or providing a silicon nitride film.

The first deposition material EM1 and the second deposition material EM2 may include substantially the same material, but are provided by different methods, and therefore, the first sub-layer IL-S1 that corresponds to the preliminary first inorganic layer PIL and the second sub-layer IL-S2 formed or provided on the first sub-layer IL-S1 may have different densities. The first sub-layer IL-S1 may have a relatively high density. The second sub-layer IL-S2 may be formed or provided directly on the first sub-layer IL-S1 and may have a relatively low density. Because the first sub-layer IL-S1 corresponds to the preliminary first inorganic layer PIL formed or provided by a plasma-enhanced atomic layer deposition (PEALD) method and/or the like, it may have a relatively high density. The second sub-layer IL-S2 may be formed or provided by a plasma-enhanced chemical vapor deposition (PECVD) method, and a low-density film may be formed or provided in the early stage of film formation during the plasma-enhanced chemical vapor deposition process, and therefore, the second sub-layer IL-S2 may have a relatively low density. The third sub-layer IL-S3 may be formed or provided by a plasma-enhanced chemical vapor deposition method in substantially the same manner as the second sub-layer IL-S2. However, because the film is formed or provided after the middle stage of the deposition process, the density of the third sub-layer IL-S3 may be higher than that of the second sub-layer IL-S2. The density difference between the second sub-layer IL-S2 and the first sub-layer IL-S1 may be about 0.1 g/cm³ or more.

FIG. 12 illustrates a portion of a cross section in which the preliminary first inorganic layer PIL is formed or provided by the first deposition material during the step of manufacturing the first inorganic layer.

Referring to FIG. 12, a portion of the preliminary first inorganic layer PIL, which is disposed or provided around the tip portion TP, may not have a uniform (e.g., substantially uniform) thickness due to an undercut UCP structure, and a portion thereof may have a thickness smaller than that of the other portions.

The preliminary first inorganic layer PIL may include a first preliminary portion PIL-1 disposed or provided on the upper surface MTP-U of the tip portion TP of the protrusion pattern MTP, a second preliminary portion PIL-2 disposed or provided on the lower surface MTP-B of the tip portion TP, and a third preliminary portion PIL-3 disposed or provided on the first inclined surface IS1. The preliminary first inorganic layer PIL may further include a fourth preliminary portion PIL-4 disposed or provided on the side surface MTP-S of the tip portion TP. The first preliminary portion PIL-1 to the fourth preliminary portion PIL-4 may have an integrated shape (e.g., a substantially integrated shape) or may partially have different thicknesses. By the first preliminary portion PIL-1 to the fourth preliminary portion PIL-4, the preliminary first inorganic layer PIL may entirely (e.g., substantially entirely) cover each of the upper surface MTP-U, the lower surface MTP-B, and the side surface MTP-S of the tip portion TP, and the first inclined surface IS1 of the first dam layer DM1-B and DM2-B.

In the preliminary first inorganic layer PIL according to one or more embodiments of the present disclosure, the first preliminary portion PIL-1 disposed or provided on the upper surface MTP-U of the tip portion TP may have a greater thickness than the other portions. A thickness Tb of the second preliminary portion PIL-2 disposed or provided on the lower surface MTP-B of the tip portion TP may be about 50% or more of a thickness Ta of the first preliminary portion PIL-1. The thickness Tb of the second preliminary portion PIL-2 may be about 50% to about 80% of the thickness Ta of the first preliminary portion PIL-1. A thickness Tc of the third preliminary portion PIL-3 disposed or provided on the first inclined surface IS1 may be about 80% or more of the thickness Ta of the first preliminary portion PIL-1. The thickness Tc of the third preliminary portion PIL-3 may be about 80% to about 90% of the thickness Ta of the first preliminary portion PIL-1. A thickness Td of the fourth preliminary portion PIL-4 disposed or provided on the side surface MTP-S of the tip portion TP may be about 85% or more of the thickness Ta of the first preliminary portion PIL-1. The thickness Td of the fourth preliminary portion PIL-4 may be about 85% to about 95% of the thickness Ta of the first preliminary portion PIL-1.

In the method of manufacturing the electronic device according to one or more embodiments of the present disclosure, because the preliminary first inorganic layer PIL may be formed or provided by the first method as described in one or more embodiments, the thickness of the preliminary first inorganic layer PIL in the undercut UCP portion may be formed or provided to be a set or predetermined thickness or more. In one or more embodiments, hereafter, if (e.g., when) the first inorganic layer IOL1 is completed by the second method, the thickness of the first inorganic layer IOL1 in the undercut UCP portion may be formed or provided to be a set or predetermined thickness or more, thereby improving or enhancing the reliability of the display module DM. Because the method for manufacturing the electronic device according to one or more embodiments of the present disclosure includes a process of forming or providing the preliminary first inorganic layer PIL by the first method, the thickness of the first inorganic layer IOL1 in the undercut UCP portion, for example, the thickness of each of the second portion IOL1-2 (see FIG. 8), the third portion IOL1-3 (see FIG. 8), and the fourth portion IOL1-4 (see FIG. 8), as described in one or more embodiments, may be formed or provided to be greater, compared to a case in which the process of forming or providing the preliminary first inorganic layer PIL is not included. Accordingly, it may be feasible to reduce the water vapor transmission rate of the electronic device including the first inorganic layer IOL1 and improve or enhance the reliability thereof.

Because the electronic device according to one or more embodiments of the present disclosure includes an inorganic encapsulation layer including a plurality of sub-layers having different densities, the thickness of the inorganic encapsulation layer in an undercut portion formed or provided by a dam structure and a groove provided adjacent to a module hole may be provided to be a set or predetermined thickness or more. Accordingly, as the water vapor transmission rate of the encapsulation layer is low, the display panel may be effectively or suitably protected, and the electronic device may exhibit excellent or suitable reliability characteristics.

Although one or more embodiments of the present disclosure have been described with reference to the accompanying drawings, it should be understood that the present disclosure should not be limited to these embodiments but one or more suitable changes and modifications can be made within the spirit and scope of the appended claims and equivalents thereof, the detailed description of the present disclosure, and the accompanying drawings.

Accordingly, the scope of the present disclosure should not be limited to one or more embodiments/examples, but should be determined by the appended claims and equivalents thereof.

What is claimed is:

1. An electronic device comprising:
an electronic module; and
a display module comprising:
a hole region defined to overlap the electronic module;
a base layer having a module hole that is defined therein and corresponds to the hole region;
a circuit layer on the base layer;
a display element layer provided on the circuit layer and comprising a light-emitting element; and
an encapsulation layer partially provided on the display element layer and comprising at least a first inorganic layer,
wherein the circuit layer comprises:
a plurality of insulating layers provided on the base layer and comprising a first intermediate insulating layer;
a first dam portion that is spaced apart from the first intermediate insulating layer and defines at least one groove therebetween; and
a protrusion pattern provided on at least a portion of the first intermediate insulating layer and the first dam portion and comprising a tip portion that protrudes in an inward direction of the at least one groove,
wherein:
the first dam portion comprises a first inclined surface below the protrusion pattern; and
the first inorganic layer comprises a first portion on an upper surface of the tip portion, a second portion on a lower surface of the tip portion, and a third portion on the first inclined surface,
wherein:
a thickness of the second portion is about 30% or more of a thickness of the first portion; and
a thickness of the third portion is about 40% or more of the thickness of the first portion.

2. The electronic device as claimed in claim 1, wherein:
the at least one groove comprises a first groove defined by the first inclined surface; and
the encapsulation layer further comprises a second inorganic layer,
at least a portion of the first inorganic layer and at least a portion of the second inorganic layer being in contact with each other in a region that overlaps the first groove.

3. The electronic device as claimed in claim 2, wherein the first inorganic layer further comprises:
a first sub-layer adjacent to the tip portion;
a second sub-layer on the first sub-layer; and
a third sub-layer on the second sub-layer,
wherein a density of the second sub-layer is lower than a density of each of the first sub-layer and the third sub-layer.

4. The electronic device as claimed in claim 3, wherein a thickness of the first sub-layer is about 0.1% to about 10% of a thickness of the first inorganic layer.

5. The electronic device as claimed in claim 3, wherein a density difference between the first sub-layer and the second sub-layer is about 0.1 g/cm³ or more.

6. The electronic device as claimed in claim 1, wherein the encapsulation layer further comprises:
a second inorganic layer on the first inorganic layer; and
an organic layer between the first inorganic layer and the second inorganic layer,
wherein the organic layer does not overlap at least a portion of the protrusion pattern in plan view.

7. The electronic device as claimed in claim 6, wherein each of the first inorganic layer and the second inorganic layer comprises silicon nitride.

8. The electronic device as claimed in claim 1, wherein:
the first dam portion comprises a first dam layer provided on substantially the same layer as the first intermediate insulating layer and arranged to provide a base surface on which the protrusion pattern is provided and a second dam layer on the protrusion pattern; and
the first inclined surface is provided to the first dam layer.

9. The electronic device as claimed in claim 1, wherein a refractive index of the first inorganic layer is about 1.7 to about 2.0 at a wavelength of about 550 nm.

10. The electronic device as claimed in claim 1, wherein a thickness of the first inorganic layer is about 1,000 Å to about 20,000 Å.

11. The electronic device as claimed in claim 1, wherein a water vapor transmission rate of the first inorganic layer is 1.0×10⁻⁴ g/(m²·day) or less.

12. The electronic device as claimed in claim 1, wherein the first inorganic layer substantially entirely covers the upper surface of the tip portion, the lower surface of the tip portion, and a side surface that connects the upper surface and the lower surface to each other.

13. The electronic device as claimed in claim 1, wherein the first inorganic layer substantially entirely covers the first inclined surface.

14. The electronic device as claimed in claim 1, wherein:
the plurality of insulating layers further comprise a first lower insulating layer below the first intermediate insulating layer,
wherein:
an upper surface of the first lower insulating layer is exposed by the at least one groove; and
the first inorganic layer is in contact with the upper surface of the first lower insulating layer.

15. The electronic device as claimed in claim 1, wherein the at least one groove is around the module hole in plan view.

16. An electronic device comprising:
an electronic module; and
a display module comprising:
a hole region defined to overlap the electronic module;
a base layer having a module hole that is defined therein and corresponds to the hole region;
a circuit layer provided on the base layer;
a display element layer provided on the circuit layer and comprising a light-emitting element; and
an encapsulation layer partially provided on the display element layer and comprising a first inorganic layer and a second inorganic layer,
wherein the circuit layer comprises:
a dam pattern provided in the hole region and comprising a first dam portion and a second dam portion; and
a protrusion pattern on at least a portion of the dam pattern,
wherein:
a first groove is defined between the first dam portion and the second dam portion;
the protrusion pattern comprises a tip portion that protrudes in an inward direction of the first groove;
each of the first dam portion and the second dam portion comprises a first inclined surface that is below the protrusion pattern and defines the first groove; and
the first inorganic layer comprises a first portion on an upper surface of the tip portion, a second portion on a lower surface of the tip portion, and a third portion on the first inclined surface,
wherein:
a thickness of the second portion is about 30% or more of a thickness of the first portion; and
a thickness of the third portion is about 40% or more of the thickness of the first portion.

17. A method for manufacturing an electronic device, the method comprising:
providing a base layer having a module hole defined therein;
providing a circuit layer comprising a plurality of insulating layers on the base layer, a dam pattern spaced apart from the plurality of insulating layers, and a protrusion pattern; and
providing an encapsulation layer on the circuit layer,
wherein:
the dam pattern comprises a first dam portion that is spaced apart from the plurality of insulating layers and defines at least one groove therebetween;
the protrusion pattern is on at least a portion of the first dam portion;
the first dam portion comprises a first inclined surface below the protrusion pattern; and
the protrusion pattern comprises a tip portion that protrudes from the first inclined surface,
wherein:
the providing of the encapsulation layer comprises providing a first inorganic layer that covers the tip portion and the first inclined surface; and
the first inorganic layer comprises a first portion on an upper surface of the tip portion, a second portion on a lower surface of the tip portion, and a third portion on the first inclined surface,
wherein:
a thickness of the second portion is about 30% or more of a thickness of the first portion; and
a thickness of the third portion is about 40% or more of the thickness of the first portion.

18. The method as claimed in claim 17, wherein the providing of the first inorganic layer comprises:
applying a first deposition material by any one selected from among a plasma-enhanced atomic layer deposition (PEALD) method, a sputtering method, and an electron beam evaporator method to provide a preliminary first inorganic layer; and
applying a second deposition material on the preliminary first inorganic layer by a plasma-enhanced chemical vapor deposition (PECVD) method.

19. The method as claimed in claim 18, wherein a thickness of the preliminary first inorganic layer is about 0.1% to about 10% of a total thickness of the first inorganic layer.

20. The method as claimed in claim 18, wherein the first inorganic layer comprises:
a first sub-layer to correspond to the preliminary first inorganic layer;
a second sub-layer on the first sub-layer; and
a third sub-layer on the second sub-layer,
wherein a density of the second sub-layer is lower than a density of each of the first sub-layer and the third sub-layer.
